(19) United States
(12) Patent Application Publication
(10) Pub. No.: US 2026/0291689 A1
(43) Pub. Date: Sep. 24, 2026

(54) METHOD, APPARATUS, AND SYSTEM FOR JOINT UPLINK ENCODING AND DECODING

(71) Applicant: Huawai Technologies Co., Ltd., Shenzhen (CN)

(72) Inventors: Yu Cao, Ottawa (CA); Huazi Zhang, Zhejiang (CN); Van Hung Vu, Gatineau (CA); Haoyuan Wei, Stittsville (CA)

(21) Appl. No.: 19/679,433

(22) Filed: May 15, 2026

Related U.S. Application Data
(63) Continuation of application No. PCT/CN2024/078052, filed on Feb. 22, 2024.
(60) Provisional application No. 63/600,164, filed on Nov. 17, 2023.

(51) Int. Cl. H04L 5/00; H04L 1/00

(52) U.S. Cl. CPC H04L 5/0053; H04L 1/0057

(57) ABSTRACT

The present disclosure relates to joint uplink encoding and decoding. In an example method, input bits that include data bits and bits associated with control information are encoded to generate coded bits, and in another example method, the coded bits can be decoded to recover the data bits and the bits associated with the control information. The encoding involves jointly encoding the data bits and the bits associated with the control information according to a first code that is different from a second code according to which second coded bits are generated from the control information.

### CROSS-REFERENCE TO RELATED APPLICATIONS

The present application is a continuation of International Patent Application PCT/CN2024/078052, filed on Feb. 22, 2024, which claims the benefit of and priority to U.S. Provisional Application No. 63/600,164, entitled “Method, Apparatus, and System for Joint Uplink Encoding and Decoding,” filed on Nov. 17, 2023. The entire contents of the aforementioned applications are hereby incorporated by reference.

### TECHNICAL FIELD

The present application relates to coding for wireless communications, and in particular to joint coding of control information and data.

### BACKGROUND

Mixed traffic coding considers multiple services (at least two services) with different traffic types. A first traffic type (URLLC for example) may be protected by a small code (small code length) while a second traffic type (eMBB for example) may be protected by a larger code because of large payload. Examples of mixed traffic coding embed part or all of the information bits from the small code into the payload of the larger code and encode them together in the larger code. Decoding the small code can enhance the decoding of the larger code, while decoding of larger code can also improve the reliability of the small code if the small code cannot be independently decoded, which reduces the likelihood of retransmission for the small code.

Such mixed traffic coding may enhance decoding of traffic. It may be desirable to provide enhanced control information reliability.

### SUMMARY

Some aspects of the present disclosure add a procedure between a decoding failure and a request for a retransmission.

Some aspects of the present disclosure relate to a channel coding design that supports both self decodability and enhanced joint decodability.

Some aspects of the present disclosure relate to a three-decoding-attempt transmission method. The method may include a procedure called joint decoding, which is inserted between a decoding failure and a retransmission request.

In some embodiments, a procedure for mixed traffic coding may be also applicable to joint encoding of control and data information. However, in many scenarios, the control information and data information may be encoded by different coding types. For example, control information may be encoded by a Polar code, which is usually decoded using a hard-decision decoder while the data information may be encoded by a LDPC code, which can use a soft-in soft-out decoder. In some examples of this disclosure, a method for joint encoding of control and data to enhance control information reliability is described. Furthermore, the control channel may be also separately encoded and transmitted to maintain self decodability. One example for the application of the joint encoding of control and data is to apply it to UCI and UL data (UL-SCH) multiplexing.

According to an aspect of the present disclosure, a method involves encoding input bits to generate coded bits, and outputting the coded bits. The input bits include data bits and bits associated with control information, and the encoding involves jointly encoding the data bits and the bits associated with the control information. Jointly encoding the data bits and the bits associated with the control information involves jointly encoding the data bits and the bits associated with the control information according to a first code that is different from a second code according to which second coded bits are generated from the control information.

Another method disclosed herein involves receiving coded bits generated by jointly encoding input bits that include data bits and bits associated with control information, and outputting recovered data bits and bits associated with the control information decoded from the received coded bits. The input bits in this example have been jointly encoded according to a first code that is different from a second code according to which second coded bits were generated from the control information.

An apparatus according to an embodiment includes an encoder for encoding input bits to generate coded bits, and an interface, coupled to the encoder, for outputting the coded bits. The input bits include data bits and bits associated with control information, and the encoding involves jointly encoding the data bits and the bits associated with the control information. Jointly encoding the data bits and the bits associated with the control information involves jointly encoding the data bits and the bits associated with the control information according to a first code that is different from a second code according to which second coded bits are generated from the control information.

According to another aspect of the present disclosure, an apparatus includes an interface for receiving coded bits generated by jointly encoding input bits, the input bits including data bits and bits associated with control information, the input bits having been jointly encoded according to a first code that is different from a second code according to which second coded bits were generated from the control information. Such an apparatus may also include a decoder, coupled to the interface, for decoding, from the received coded bits, recovered data bits and bits associated with the control information.

In other apparatus embodiments, an apparatus may include a processor configured to cause the apparatus to perform any of the methods as disclosed herein.

An apparatus may include a processor and a non-transitory computer readable storage medium that is coupled to the processor and stores programming for execution by the processor.

A storage medium need not necessarily or only be implemented in or in conjunction with such an apparatus. A computer program product, for example, may be or include a non-transitory computer readable medium storing programming for execution by a processor.

Programming stored by a computer readable storage medium may include instructions to, or to cause a processor to, perform, implement, support, or enable any of the methods disclosed herein.

A system is also disclosed, and may include: a first communication device configured to encode input bits to generate coded bits, and to transmit the coded bits; and a second communication device configured to receive and decode the coded bits. The input bits include data bits and bits associated with control information, and the input bits are encoded by jointly encoding the data bits and the bits associated with the control information. Jointly encoding the data bits and the bits associated with the control information involves jointly encoding the data bits and the bits associated with the control information according to a first code that is different from a second code according to which second coded bits are generated from the control information.

The present disclosure encompasses these and other aspects or embodiments.

### BRIEF DESCRIPTION OF THE DRAWINGS

For a more complete understanding of the present embodiments, and the advantages thereof, reference is now made, byway of example, to the following descriptions taken in conjunction with the accompanying drawings.

FIG. 1 is a simplified schematic illustration of a communication system.

FIG. 2 is a block diagram illustration of the example communication system in FIG. 1.

FIG. 3 illustrates an example electronic device and examples of base stations.

FIG. 4 illustrates units or modules in a device.

FIG. 5 illustrates self-decoding and joint-decoding.

FIG. 6 illustrates a robot arm that includes a video device and two joints, and communicates with a base station.

FIG. 7 illustrates an example code block and encoded symbols.

FIG. 8 illustrates another example code block and encoded symbols.

FIG. 9 illustrates yet another example code block and encoded symbols.

FIG. 10 illustrates sequential coupling of bits between individual payloads.

FIG. 11 illustrates multi-to-one coupling of bits between individual payloads.

FIG. 12 illustrates an example application and joint UCI and UL data transmission procedure.

FIG. 13 illustrates an example of joint UCI and UL-SCH coding.

FIG. 14 illustrates an example of embedding entire UCI coded bits into UL data.

FIG. 15 illustrates an example of embedding different parts of coded bits from UCI.

FIG. 16 illustrates an example of high priority UCI coupling.

FIG. 17 illustrates an example of UCI rate matching considering coupling bits.

FIG. 18 illustrates a decoding example.

FIG. 19 illustrates an example of a UCI and UL-SCH resource multiplexing procedure.

FIG. 20 illustrates a resource mapping example.

FIG. 21 illustrates example methods according to embodiments.

FIG. 22 illustrates apparatus according to embodiments.

### DETAILED DESCRIPTION OF ILLUSTRATIVE EMBODIMENTS

For illustrative purposes, specific example embodiments will now be explained in greater detail in conjunction with the figures.

The embodiments set forth herein represent information sufficient to practice the claimed subject matter and illustrate ways of practicing such subject matter. Upon reading the following description in light of the accompanying figures, those of skill in the art will understand the concepts of the claimed subject matter and will recognize applications of these concepts not particularly addressed herein. It should be understood that these concepts and applications fall within the scope of the disclosure and the accompanying claims.

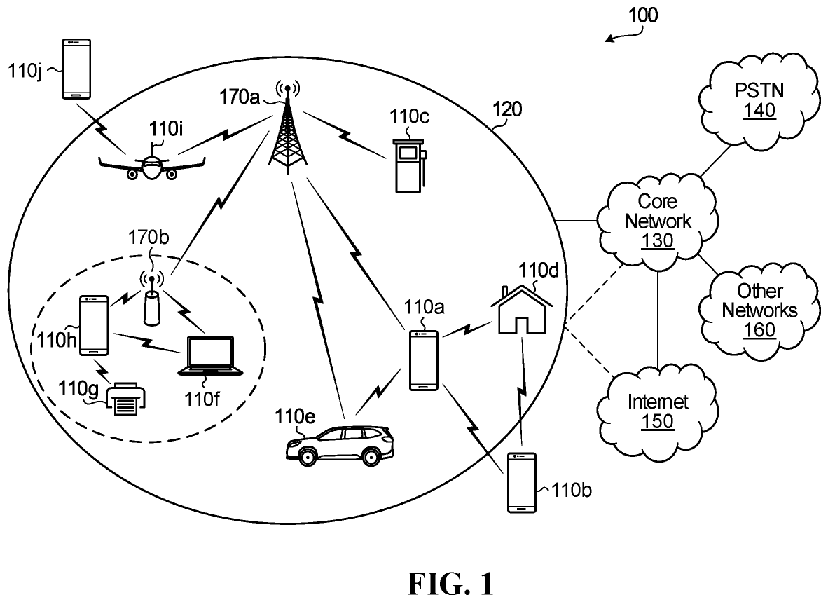

Referring to FIG. 1, as an illustrative example without limitation, a simplified schematic illustration of a communication system is provided. The communication system 100 comprises a radio access network 120. The radio access network 120 may be a next generation (sixth generation (6G) or later for example) radio access network, or a legacy (5G, 4G, 3G or 2G for example) radio access network. One or more communication electronic devices (ED) 110a, 110b, 110c, 110d, 110e, 110f, 110g, 110h, 110i, 110j (generically referred to as 110) may be interconnected to one another or connected to one or more network nodes (170a, 170b, generically referred to as 170) in the radio access network 120. A core network 130 may be a part of the communication system and may be dependent or independent of the radio access technology used in the communication system 100. Also the communication system 100 comprises a public switched telephone network (PSTN) 140, the internet 150, and other networks 160.

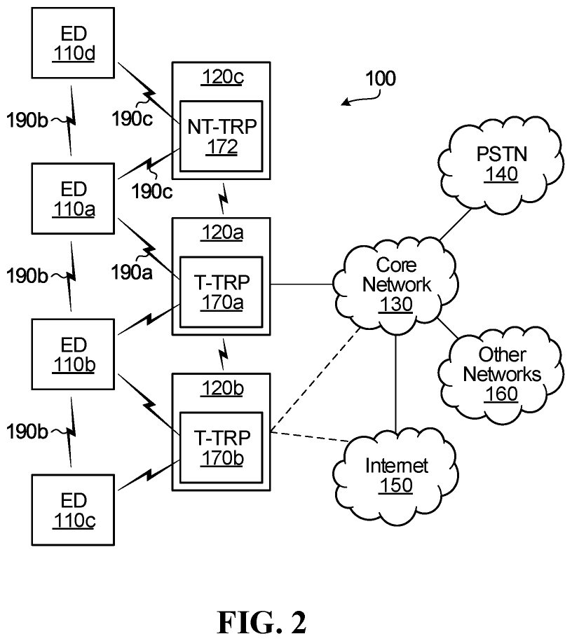

FIG. 2 illustrates an example communication system 100. In general, the communication system 100 enables multiple wireless or wired elements to communicate data and other content. The purpose of the communication system 100 may be to provide content, such as voice, data, video, and/or text, via broadcast, multicast, groupcast, unicast, and so on. The communication system 100 may operate by sharing resources, such as carrier spectrum bandwidth, between its constituent elements. The communication system 100 may include a terrestrial communication system and/or a non-terrestrial communication system. The communication system 100 may provide a wide range of communication services and applications (such as earth monitoring, remote sensing, passive sensing and positioning, navigation and tracking, autonomous delivery and mobility, and so on). The communication system 100 may provide a high degree of availability and robustness through a joint operation of a terrestrial communication system and a non-terrestrial communication system. For example, integrating a non-terrestrial communication system (or components thereof) into a terrestrial communication system can result in what may be considered a heterogeneous network comprising multiple layers. Compared to conventional communication networks, the heterogeneous network may achieve better overall performance through efficient multi-link joint operation, more flexible functionality sharing, and faster physical layer link switching between terrestrial networks and non-terrestrial networks.

The terrestrial communication system and the non-terrestrial communication system could be considered sub-systems of the communication system. In the example shown in FIG. 2, the communication system 100 includes electronic devices (ED) 110a, 110b, 110c, 110d (generically referred to as ED 110), radio access networks (RANs) 120a, 120b, a non-terrestrial communication network 120c, a core network 130, a public switched telephone network (PSTN) 140, the Internet 150, and other networks 160. The RANs 120a, 120b include respective base stations (BSs) 170a, 170b, which may be generically referred to as terrestrial transmit and receive points (T-TRPs) 170a, 170b. The non-terrestrial communication network 120c includes an access node 172, which may be generically referred to as a non-terrestrial transmit and receive point (NT-TRP) 172.

Any ED 110 may be alternatively or additionally configured to interface, access, or communicate with any T-TRP 170a,170b and NT-TRP 172, the Internet 150, the core network 130, the PSTN 140, the other networks 160, or any combination of the preceding. In some examples, ED 110a may communicate an uplink and/or downlink transmission over a terrestrial air interface 190a with T-TRP 170a. In some examples, the EDs 110a, 110b, 110c, and 110d may also communicate directly with one another via one or more sidelink air interfaces 190b. In some examples, ED 110d may communicate an uplink and/or downlink transmission over a non-terrestrial air interface 190c with NT-TRP 172.

The air interfaces 190a and 190b may use similar communication technology, such as any suitable radio access technology. For example, the communication system 100 may implement one or more channel access methods, such as code division multiple access (CDMA), space division multiple access (SDMA), time division multiple access (TDMA), frequency division multiple access (FDMA), orthogonal FDMA (OFDMA), or single-carrier FDMA (SC-FDMA, also known as discrete Fourier transform spread OFDMA, DFT-s-OFDMA) in the air interfaces 190a and 190b. The air interfaces 190a and 190b may utilize other higher dimension signal spaces, which may involve a combination of orthogonal and/or non-orthogonal dimensions.

The non-terrestrial air interface 190c can enable communication between the ED 110d and one or multiple NT-TRPs 172 via a wireless link or simply a link. For some examples, the link is a dedicated connection for unicast transmission, a connection for broadcast transmission, or a connection between a group of EDs 110 and one or multiple NT-TRPs 172 for multicast transmission.

The RANs 120a and 120b are in communication with the core network 130 to provide the EDs 110a 110b, and 110c with various services such as voice, data, and other services. The RANs 120a and 120b and/or the core network 130 may be in direct or indirect communication with one or more other RANs (not shown), which may or may not be directly served by core network 130, and may or may not employ the same radio access technology as RAN 120a, RAN 120b or both. The core network 130 may also serve as a gateway access between (i) the RANs 120a and 120b or EDs 110a 110b, and 110c or both, and (ii) other networks (such as the PSTN 140, the Internet 150, and the other networks 160). In addition, some or all of the EDs 110a 110b, and 110c may include functionality for communicating with different wireless networks over different wireless links using different wireless technologies and/or protocols. Instead of wireless communication (or in addition thereto), the EDs 110a 110b, and 110c may communicate via wired communication channels to a service provider or switch (not shown), and to the Internet 150. PSTN 140 may include circuit switched telephone networks for providing plain old telephone service (POTS). Internet 150 may include a network of computers and subnets (intranets) or both, and incorporate protocols, such as Internet Protocol (IP), Transmission Control Protocol (TCP), User Datagram Protocol (UDP). EDs 110a 110b, and 110c may be multimode devices capable of operation according to multiple radio access technologies, and incorporate multiple transceivers necessary to support such.

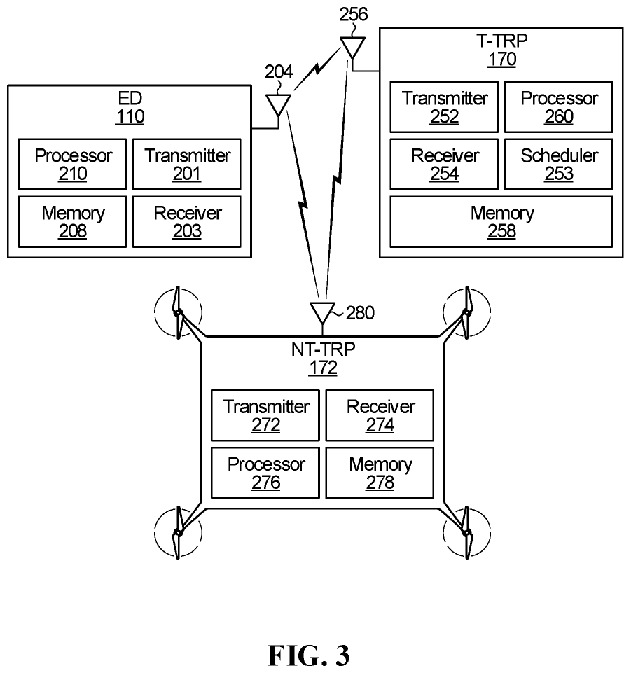

FIG. 3 illustrates another example of an ED 110 and a base station 170a, 170b and/or 170c. The ED 110 is used to connect persons, objects, machines, and so on. The ED 110 may be widely used in various scenarios including, for example, cellular communications, device-to-device (D2D), vehicle to everything (V2X), peer-to-peer (P2P), machine-to-machine (M2M), machine-type communications (MTC), internet of things (IoT), virtual reality (VR), augmented reality (AR), mixed reality (MR), metaverse, digital twin, industrial control, self-driving, remote medical, smart grid, smart furniture, smart office, smart wearable, smart transportation, smart city, drones, robots, remote sensing, passive sensing, positioning, navigation and tracking, autonomous delivery and mobility, and so on.

Each ED 110 represents any suitable end user device for wireless operation and may include such devices (or may be referred to) as a user equipment/device (UE), a wireless transmit/receive unit (WTRU), a mobile station, a fixed or mobile subscriber unit, a cellular telephone, a station (STA), a machine type communication (MTC) device, a personal digital assistant (PDA), a smartphone, a laptop, a computer, a tablet, a wireless sensor, a consumer electronics device, a smart book, a vehicle, a car, a truck, a bus, a train, or an IoT device, wearable devices (such as a watch, a pair of glasses, head mounted equipment, and so on), an industrial device, or an apparatus in (for example a communication module, modem, or chip) or comprising the forgoing devices, among other possibilities. Future generation EDs no may be referred to using other terms. The base station 170a and 170b is a T-TRP and will hereafter be referred to as T-TRP 170. Also shown in FIG. 3, a NT-TRP will hereafter be referred to as NT-TRP 172. Each ED no connected to T-TRP 170 and/or NT-TRP 172 can be dynamically or semi-statically turned-on (that is, established, activated, or enabled), turned-off (that is, released, deactivated, or disabled) and/or configured in response to one of more of: connection availability and connection necessity.

The ED 110 includes a transmitter 201 and a receiver 203 coupled to one or more antennas 204. Only one antenna 204 is illustrated to avoid congestion in the drawing. One, some, or all of the antennas 204 may alternatively be panels. The transmitter 201 and the receiver 203 may be integrated, for example as a transceiver. The transceiver is configured to modulate data or other content for transmission by at least one antenna 204 or network interface controller (NIC). The transceiver is also configured to demodulate data or other content received by the at least one antenna 204. Each transceiver includes any suitable structure for generating signals for wireless or wired transmission and/or processing signals received wirelessly or by wire. Each antenna 204 includes any suitable structure for transmitting and/or receiving wireless or wired signals.

The ED 110 includes at least one memory 208. The memory 208 stores instructions and data used, generated, or collected by the ED 110. For example, the memory 208 could store software instructions or modules configured to implement some or all of the functionality and/or embodiments described herein and that are executed by one or more processing unit(s) (for example, a processor 210). Each memory 208 includes any suitable volatile and/or non-volatile storage and retrieval device(s). Any suitable type of memory may be used, such as random access memory (RAM), read only memory (ROM), hard disk, optical disc, subscriber identity module (SIM) card, memory stick, secure digital (SD) memory card, on-processor cache, and the like.

The ED 110 may further include one or more input/output devices (not shown) or interfaces (such as a wired interface to the Internet 150 in FIG. 1). The input/output devices or interfaces permit interaction with a user or other devices in the network. Each input/output device or interface includes any suitable structure for providing information to or receiving information from a user, and/or for network interface communications. Suitable structures include, for example, a speaker, microphone, keypad, keyboard, display, touch screen, and so on.

The ED 110 includes the processor 210 for performing operations including those operations related to preparing a transmission for uplink transmission to the NT-TRP 172 and/or the T-TRP 170; those operations related to processing downlink transmissions received from the NT-TRP 172 and/or the T-TRP 170; and those operations related to processing sidelink transmission to and from another ED 110. Processing operations related to preparing a transmission for uplink transmission may include operations such as encoding, modulating, transmit beamforming, and generating symbols for transmission. Processing operations related to processing downlink transmissions may include operations such as receive beamforming, demodulating and decoding received symbols. Depending upon the embodiment, a downlink transmission may be received by the receiver 203, possibly using receive beamforming, and the processor 210 may extract signaling from the downlink transmission (for example by detecting and/or decoding the signaling). An example of signaling may be a reference signal transmitted by the NT-TRP 172 and/or by the T-TRP 170. In some embodiments, the processor 210 implements the transmit beamforming and/or the receive beamforming based on the indication of beam direction, for example beam angle information (BAI), received from the T-TRP 170. In some embodiments, the processor 210 may perform operations relating to network access (for example initial access) and/or downlink synchronization, such as operations relating to detecting a synchronization sequence, decoding and obtaining the system information, and so on. In some embodiments, the processor 210 may perform channel estimation, for example using a reference signal received from the NT-TRP 172 and/or from the T-TRP 170.

Although not illustrated, the processor 210 may form part of the transmitter 201 and/or part of the receiver 203. Although not illustrated, the memory 208 may form part of the processor 210.

The processor 210, the processing components of the transmitter 201, and the processing components of the receiver 203 may each be implemented by the same or different one or more processors that are configured to execute instructions stored in a memory (for example in the memory 208). Alternatively, some or all of the processor 210, the processing components of the transmitter 201, and the processing components of the receiver 203 may each be implemented using dedicated circuitry, such as a programmed field-programmable gate array (FPGA), an application-specific integrated circuit (ASIC), or a hardware accelerator such as a graphics processing unit (GPU) or an artificial intelligence (AI) accelerator.

The T-TRP 170 may be known by other names in some implementations, such as a base station, a base transceiver station (BTS), a radio base station, a network node, a network device, a device on the network side, a transmit/receive node, a Node B, an evolved NodeB (eNodeB or eNB), a Home eNodeB, a next Generation NodeB (gNB), a transmission point (TP), a site controller, an access point (AP), a wireless router, a relay station, a terrestrial node, a terrestrial network device, a terrestrial base station, a base band unit (BBU), a remote radio unit (RRU), an active antenna unit (AAU), a remote radio head (RRH), a central unit (CU), a distributed unit (DU), a positioning node, among other possibilities. The T-TRP 170 may be a macro BS, a pico BS, a relay node, a donor node, or the like, or combinations thereof. The T-TRP 170 may refer to the forgoing devices or refer to apparatus (for example a communication module, a modem, or a chip) in the forgoing devices.

In some embodiments, the parts of the T-TRP 170 may be distributed. For example, some of the modules of the T-TRP 170 may be located remote from the equipment that houses the antennas 256 for the T-TRP 170, and may be coupled to the equipment that houses the antennas 256 over a communication link (not shown) sometimes known as front haul, such as common public radio interface (CPRI). Therefore, in some embodiments, the term T-TRP 170 may also refer to modules on the network side that perform processing operations, such as determining the location of the ED 110, resource allocation (scheduling), message generation, and encoding/decoding, and that are not necessarily part of the equipment that houses the antennas 256 of the T-TRP 170. The modules may also be coupled to other T-TRPs. In some embodiments, the T-TRP 170 may actually be a plurality of T-TRPs that are operating together to serve the ED 110, for example through the use of coordinated multipoint transmissions.

The T-TRP 170 includes at least one transmitter 252 and at least one receiver 254 coupled to one or more antennas 256. Only one antenna 256 is illustrated to avoid congestion in the drawing. One, some, or all of the antennas 256 may alternatively be panels. The transmitter 252 and the receiver 254 may be integrated as a transceiver. The T-TRP 170 further includes a processor 260 for performing operations including those related to: preparing a transmission for downlink transmission to the ED 110, processing an uplink transmission received from the ED 110, preparing a transmission for backhaul transmission to the NT-TRP 172, and processing a transmission received over backhaul from the NT-TRP 172. Processing operations related to preparing a transmission for downlink or backhaul transmission may include operations such as encoding, modulating, precoding (for example multiple input multiple output (MIMO) precoding), transmit beamforming, and generating symbols for transmission. Processing operations related to processing received transmissions in the uplink or over backhaul may include operations such as receive beamforming, demodulating received symbols, and decoding received symbols. The processor 260 may also perform operations relating to network access (for example initial access) and/or downlink synchronization, such as generating the content of synchronization signal blocks (SSBs), generating the system information, and so on. In some embodiments, the processor 260 also generates an indication of beam direction, for example BAI, which may be scheduled for transmission by a scheduler 253. The processor 260 performs other network-side processing operations described herein, such as determining the location of the ED 110, determining where to deploy the NT-TRP 172, and so on. In some embodiments, the processor 260 may generate signaling, for example to configure one or more parameters of the ED 110 and/or one or more parameters of the NT-TRP 172. Any signaling generated by the processor 260 is sent by the transmitter 252. Note that “signaling”, as used herein, may alternatively be called control signaling. Signaling may be transmitted in a physical layer control channel, for example a physical downlink control channel (PDCCH), in which case the signaling may be known as dynamic signaling. Signaling transmitted in a downlink physical layer control channel may be known as Downlink Control Information (DCI). Signaling transmitted in an uplink physical layer control channel may be known as Uplink Control Information (UCI). Signaling transmitted in a sidelink physical layer control channel may be known as Sidelink Control Information (SCI). Signaling may be included in a higher-layer (for example, higher than physical layer) packet transmitted in a physical layer data channel, for example in a physical downlink shared channel (PDSCH), in which case the signaling may be known as higher-layer signaling, static signaling, or semi-static signaling. Higher-layer signaling may also refer to Radio Resource Control (RRC) protocol signaling or Media Access Control-Control Element (MAC-CE) signaling.

The scheduler 253 may be coupled to the processor 260. The scheduler 253 may be included within or operated separately from the T-TRP 170. The scheduler 253 may schedule uplink, downlink, sidelink, and/or backhaul transmissions, including issuing scheduling grants and/or configuring scheduling-free (for example, “configured grant”) resources. The T-TRP 170 further includes a memory 258 for storing information and data. The memory 258 stores instructions and data used, generated, or collected by the T-TRP 170. For example, the memory 258 could store software instructions or modules configured to implement some or all of the functionality and/or embodiments described herein and that are executed by the processor 260.

Although not illustrated, the processor 260 may form part of the transmitter 252 and/or part of the receiver 254. Also, although not illustrated, the processor 260 may implement the scheduler 253. Although not illustrated, the memory 258 may form part of the processor 260.

The processor 260, the scheduler 253, the processing components of the transmitter 252, and the processing components of the receiver 254 may each be implemented by the same or different one or more processors that are configured to execute instructions stored in a memory, for example in the memory 258. Alternatively, some or all of the processor 260, the scheduler 253, the processing components of the transmitter 252, and the processing components of the receiver 254 may be implemented using dedicated circuitry, such as a programmed FPGA, a hardware accelerator (for example, a GPU or AI accelerator), or an ASIC.

Although the NT-TRP 172 is illustrated as a drone only as an example, the NT-TRP 172 may be implemented in any suitable non-terrestrial form, such as satellites and high altitude platforms, including international mobile telecommunication base stations and unmanned aerial vehicles, for example. Also, the NT-TRP 172 may be known by other names in some implementations, such as a non-terrestrial node, a non-terrestrial network device, or a non-terrestrial base station. The NT-TRP 172 includes a transmitter 272 and a receiver 274 coupled to one or more antennas 280. Only one antenna 280 is illustrated to avoid congestion in the drawing. One, some, or all of the antennas may alternatively be panels. The transmitter 272 and the receiver 274 may be integrated as a transceiver. The NT-TRP 172 further includes a processor 276 for performing operations including those related to: preparing a transmission for downlink transmission to the ED 110, processing an uplink transmission received from the ED 110, preparing a transmission for backhaul transmission to T-TRP 170, and processing a transmission received over backhaul from the T-TRP 170. Processing operations related to preparing a transmission for downlink or backhaul transmission may include operations such as encoding, modulating, precoding (for example MIMO precoding), transmit beamforming, and generating symbols for transmission. Processing operations related to processing received transmissions in the uplink or over backhaul may include operations such as receive beamforming, demodulating received symbols, and decoding received symbols. In some embodiments, the processor 276 implements the transmit beamforming and/or receive beamforming based on beam direction information (for example BAI) received from the T-TRP 170. In some embodiments, the processor 276 may generate signaling, for example to configure one or more parameters of the ED 110. In some embodiments, the NT-TRP 172 implements physical layer processing, but does not implement higher layer functions such as functions at the medium access control (MAC) or radio link control (RLC) layer. As this is only an example, more generally, the NT-TRP 172 may implement higher layer functions in addition to physical layer processing.

The NT-TRP 172 further includes a memory 278 for storing information and data. Although not illustrated, the processor 276 may form part of the transmitter 272 and/or part of the receiver 274. Although not illustrated, the memory 278 may form part of the processor 276.

The processor 276, the processing components of the transmitter 272, and the processing components of the receiver 274 may each be implemented by the same or different one or more processors that are configured to execute instructions stored in a memory, for example in the memory 278. Alternatively, some or all of the processor 276, the processing components of the transmitter 272, and the processing components of the receiver 274 may be implemented using dedicated circuitry, such as a programmed FPGA, a hardware accelerator (for example, a GPU or AI accelerator), or an ASIC. In some embodiments, the NT-TRP 172 may actually be a plurality of NT-TRPs that are operating together to serve the ED 110, e.g. through coordinated multipoint transmissions.

The T-TRP 170, the NT-TRP 172, and/or the ED 110 may include other components, but these have been omitted for the sake of clarity.

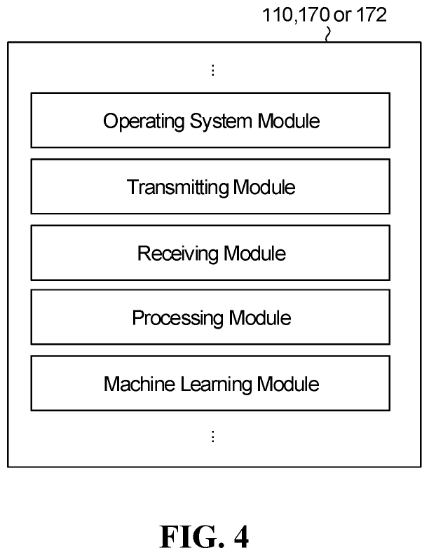

One or more steps of the embodiment methods provided herein may be performed by corresponding units or modules, according to FIG. 4. FIG. 4 illustrates units or modules in a device, such as in the ED 110, in the T-TRP 170 or in the NT-TRP 172. For example, a signal may be transmitted or output by a transmitting unit or by a transmitting module. A signal may be received or input by a receiving unit or by a receiving module. A signal may be processed by a processing unit or a processing module. Other steps may be performed by an artificial intelligence (AI) or machine learning (ML) module. The respective units or modules may be implemented using hardware, one or more components or devices that execute software, or a combination thereof. For instance, one or more of the units or modules may be a circuit such as an integrated circuit. Examples of an integrated circuit include a programmed FPGA, a GPU, or an ASIC. For instance, one or more of the units or modules may be logical such as a logical function performed by a circuit, by a portion of an integrated circuit, or by software instructions executed by a processor. It will be appreciated that where the modules are implemented using software for execution by a processor for example, the modules may be retrieved by a processor, in whole or part as needed, individually or together for processing, in single or multiple instances, and that the modules themselves may include instructions for further deployment and instantiation.

While not shown, the transmitting module and the receiving module may be part of, or combined into, a transceiver module. A transceiver module may also be known as an interface module, or simply an interface, for inputting and outputting operations.

Additional details regarding the EDs 110, the T-TRP 170, and the NT-TRP 172 are known to those of skill in the art. As such, these details are omitted here.

Having considered communications more generally above, attention will now turn to particular example embodiments.

As also discussed above, mixed traffic coding considers multiple services (at least two services) with different traffic types. One traffic type may be protected by a small code (small code length) while another traffic type may be protected by a larger code because of large payload. Examples of mixed traffic coding embed part or all of the information bits from the small code into the payload of the larger code and encode them together in the larger code. Decoding the small code can enhance the decoding of the larger code, while decoding of larger code can also improve the reliability of the small code if the small code cannot be independently decoded, which reduces the likelihood of retransmission for the small code.

A small or smaller code or code length may also be referred to as a short or shorter code or code length. Similarly, a large or larger code or code length may be referred to as a long or longer code or code length. In mixed traffic coding with part or all bits associated with a first code embedded into the payload of a second code, bits of the combined payload (including the embedded bits) are encoded together in the second code.

Some aspects of the present disclosure add a procedure between a decoding failure and a request for a retransmission. This is achieved by integrating various services into a single FEC, with awareness of service priority (target BLER, latency and sources). Some aspects of the present disclosure relate to a channel coding design that supports both self decodability and enhanced joint decodability.

Integrating various services into a single forward error correction (FEC) code is one example of integration. Embodiments are not in any way limited to different services. More generally, payload types such as control information and data, may be integrated into a single FEC code, or into a single block or payload for encoding for example. Self decodability and enhanced joint decodability are examples of other features that may be provided or supported in embodiments.

Some aspects of the present disclosure relate to a three-decoding-attempt transmission method. The method may include a procedure called joint decoding, which is inserted between a decoding failure and a retransmission request.

A three-decoding-attempt transmission paradigm is one example of an approach in which multiple decoding attempts may be made before requesting retransmission. Joint decoding is an example of a procedure that may in effect be inserted or attempted between a decoding failure and a retransmission request.

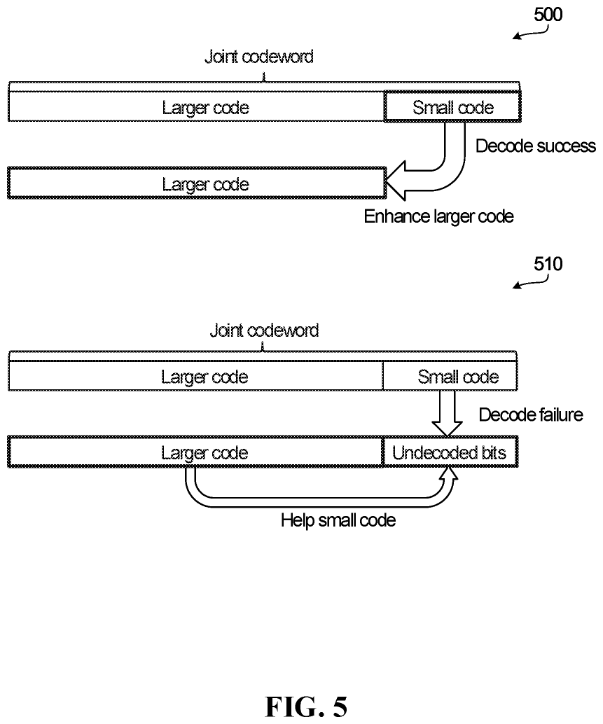

FIG. 5 illustrates self-decoding (left) and joint-decoding (right), and is referenced below in the context of this example.

In a first decoding attempt, a receiver decodes a first payload after receiving a corresponding minimum required code bits (LLRs). If the decoding of the first payload is successful, it uses the correctly decoded bits to enhance the decoding performance of a second payload after the corresponding minimum required code bits are received.

The first payload is self-decodable, and the minimum required code bits refers to the minimum number of code bits from which the first payload can possibly be decoded. LLRs refers to log-likelihood ratios as one illustrative example of code bits. Successful decoding of the first payload is shown at 500 in FIG. 5, and FIG. 5 also illustrates that the correctly decoded bits can be used to enhance decoding performance for a second payload. The corresponding minimum required code bits for the second payload refers to the minimum number of code bits from which the second payload can possibly be decoded.

Bits in a codeword, generated from encoding, may be referred to herein primarily as code bits, coded bits, or encoded bits, for example. Bits that are input to encoding or are to be encoded may be referred to as input bits, for example.

In a second decoding attempt, if the decoding of the first payload fails, the receiver will not request a retransmission, but proceed to jointly decode with the second payload. After the decoding of the second payload (no matter success or failure), the joint decoding feature can help ensure that the first payload will be successfully decoded with a high probability.

A second decoding attempt is shown at 510 in FIG. 5.

In a third decoding attempt, if the decoding of the first payload still fails after the second decoding attempt, the receiver will request a retransmission from the transmitter. This will incur some delay, but the receiver will decode a third time with both the joint code word and the retransmitted code word.

More generally with a retransmitted codeword, multiple decoding attempts may be made, to self-decode from the retransmitted codeword, jointly decode from parts of the retransmitted codeword, and/or jointly decode using both the previously received codeword and the retransmitted codeword.

Some aspects of the present disclosure relate to a self-decodable joint coding design, such that each individual payload (for example, corresponding to a service) can be self-decoded, and at the same time support joint decoding to further enhance performance.

Individual payloads may, but need not necessarily, be associated with different services. Other examples of individual payloads include control information and data.

An illustrative example a self-decodable joint coding design is outlined below:
1. Embed several small messages into a longer code block;
2. Small messages are self-decodable, meaning they can be decoded after collecting a subset of the code bits (or symbols, LLRs); the subset of code bits is also a standalone short code;
3. Two or more small messages are jointly-decodable; the corresponding subsets of the code bits combine into a longer code. This is done through “coupling” between bits from the two messages. Specifically, all or a subset of the first message (here message means information bits, that is, bits before encoding) is copied and combined with the second message. The combined message is encoded into a second code word.
   a. The bits from the first message can be directly copied and appended to the second message;
   b. The bits from the first message can be transformed (for example, multiplying with a binary matrix) and appended to the second message.

Although information bit (message) coupling is presented as an example, it is also feasible to use coded bits for coupling. In the case of systematic codes, message bits are also part of the code bits, and thus the two alternatives may be equivalent.

An example potential application scenario follows. A device (for example, robot arm) communicates with a BS and supports URLLC, eMBB and mMTC services. The video surveillance data transmissions belong to eMBB service, the signaling for controlling joints belongs to URLLC service, and some delay-insensitive sensing/monitoring data report belongs to mMTC.

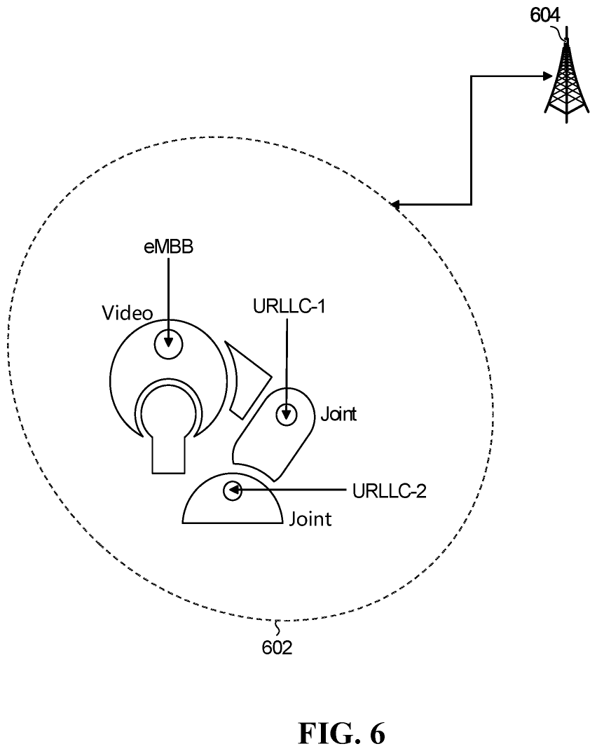

FIG. 6 is a block diagram illustrating this example, in which a robot arm 602 includes a video device and two joints, and communicates with a BS 604.

According to an approach that may be referred to as augmented eMBB coding, a joint code block comprises symbols/bits corresponding to URLLC, eMBB and mMTC packets. Each URLLC, eMBB, or mMTC packet is self-decodable. Typically, URLLC bits/symbols are placed in the beginning of the code block, followed by eMBB bits/symbols, and then mMTC bits/symbols.

The decoder first attempts to decode the short packets, for example, URLLC. If the URLLC packet can be successfully decoded, its coupled bits in the eMBB packets can augment the decoding of eMBB. The decoder can choose either to decode the eMBB packet, or the mMTC packets next. If the eMBB packet is decoded next and is successfully decoded, then the mMTC packets can be decoded with lower error probability; otherwise if the mMTC packets are decoded next and are successfully decoded, then the eMBB packet can be decoded with even lower probability.

The augmented decoding of a second packet after the successful decoding of a first packet is due to the coupling of information bits or coded bits between the two packets. In the case of coupled information bits, the other packet will have fewer information bits but its packet length remains the same, which means lower code rate. In the case of coupled coded bits, the other packet will have shortened code bits which are pre-known to the decoder, which also means lower code rate. In both cases, the code rate of at least another self-decodable codeword (say eMBB) can be reduced, therefore resulting in an improved performance.

In the example above, code bits that are pre-known are code bits that are known from decoding the first packet.

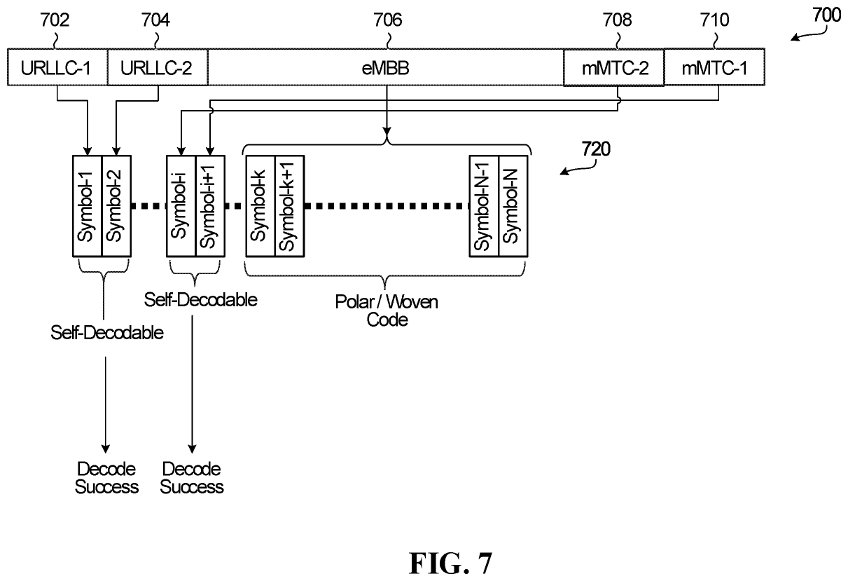

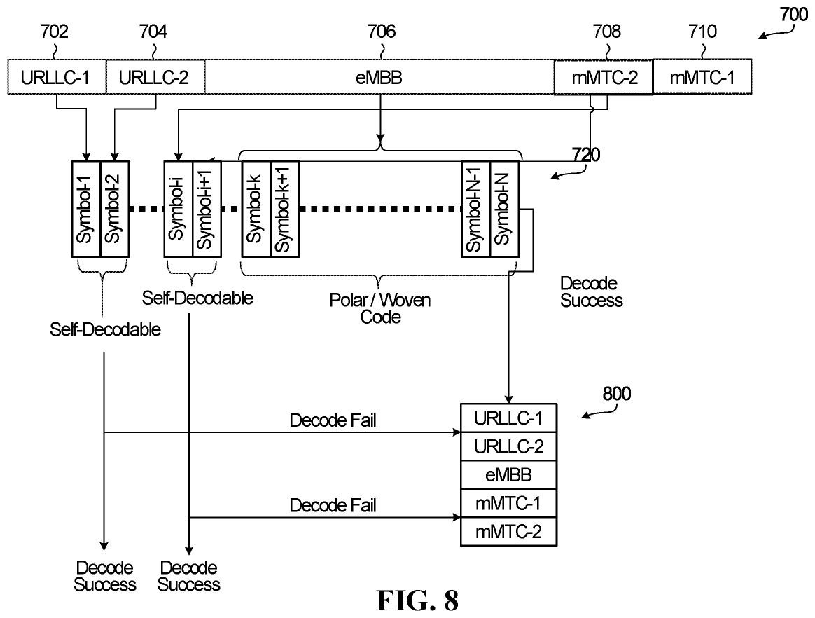

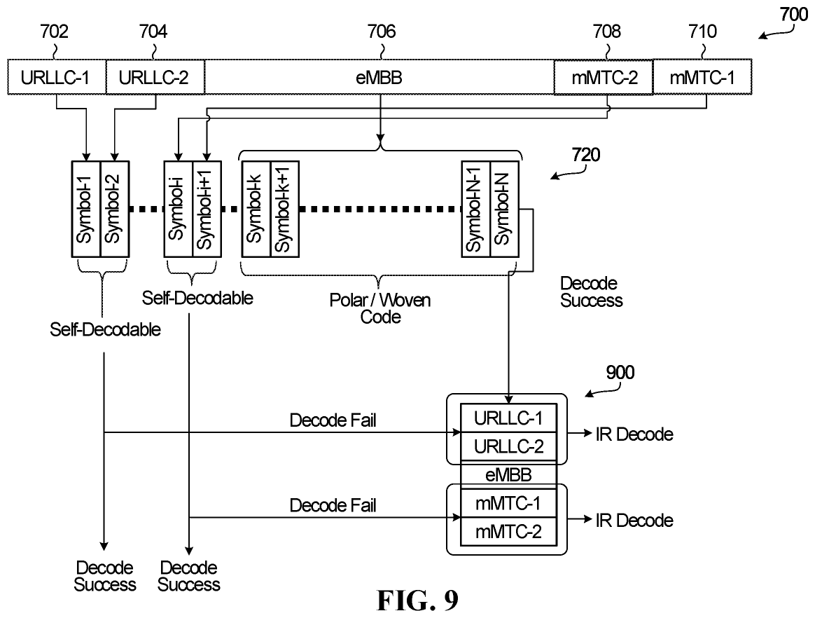

FIG. 7 is a block diagram illustrating an example code block and encoded symbols. In FIG. 7, and similarly in FIGS. 8 and 9 described below, 700 represents a code block or combined payload that includes individual payloads 702, 704, 706, 708, 710. The individual payloads 702, 704, 706, 708, 710 include payloads that are associated with different services in the example shown. The code block 700 is channel encoded to generate a codeword 720 for transmission. The codeword 720 is generated by encoding the individual payloads with an error correction code. Polar code or woven code is illustrated for the eMBB individual payload as an example. Other codes, including different codes for different individual payloads, are possible. The codeword 720 is also shown as comprising N symbols, but symbols are intended solely as an illustrative example of parts of a codeword. The arrangement of symbols shown at 720 is also an example that is intended to illustrate one possible decoding order. FIG. 7, and similarly FIGS. 8 and 9, should be interpreted accordingly.

A code block as shown at 700 may be referred to as a combined or joint code block, because it includes individual payloads, blocks, or bits, which correspond to URLLC, eMBB and mMTC services in the example shown. The URLLC, eMBB, and mMTC encoded symbols represent transmitted or received information about code bits, which are part of a codeword. The encoded symbols may be referred to by any of various names or terms, such as packets, blocks, codes, sub-codewords, signals, LLRs, resource elements (REs), etc. For ease of reference, the present disclosure refers primarily to encoded bits, encoded symbols, or encoded blocks in referring to parts of a codeword.

In the codeword 720, the URLLC, eMBB, and mMTC encoded symbols are self-decodable. Once code bits for each encoded symbol are received, that symbol can be decoded even though, in the case of the URLLC and the mMTC encoded symbols in the example shown, the entire codeword 720 has not yet been received. A self-decodable symbol may be decoded independently from other encoded symbols, in a first decoding attempt for example, and is also jointly-decodable with one or more other encoded symbols, which may (but need not necessarily be) self-decodable symbols, as disclosed herein.

Self-decodable and jointly-decodable may be referenced in the context of data before or after channel coding. For example, a short code or block that is part of a longer codeword may be considered self-decodable in that the block is decodable on its own, independently of the remainder of the longer codeword. The data that was encoded to generate that short code or block, also referred to herein as an individual payload for example, may be considered self-decodable in that the individual payload is self-decodable from the short code or block. Whether in the context of unencoded payloads or encoded symbols or packets, for example, decodable is intended to mean the same thing, specifically that individual payloads and a combined payload can be decoded from a codeword, or equivalently a codeword can be decoded to recover individual payloads and a combined payload. In other words, a payload (information bits) and a coded block or packet (code bits) can be deterministically transformed to/from each other. A payload/information bits or a code packet/code bits may be referred to as being decodable, or as being encodable.

In FIG. 7 for example, URLLC individual payloads 702, 704 are placed in the beginning of the code block 700, so that these delay-sensitive payloads may be decoded first, followed by an eMBB individual payload 706, and then mMTC individual payloads 708, 710.

At a receiver, a decoder first attempts to decode the URLLC encoded symbols or short packets, labelled Symbol-1 and Symbol-2 in FIG. 7. For illustrative purposes, the URLLC individual payloads are shown as being encoded into respective self-decodable encoded symbols, but in other embodiments encoding is based on service type, and 702, 704 are treated as one individual payload and are self-decodable together as one individual payload. If a URLLC packet can be successfully decoded, then URLLC bits, from that packet or the individual payload decoded from that packet, can assist or augment decoding of one or more other packets, or more generally one or more other blocks or sub-codewords of the long codeword 720. For example, encoded or decoded URLLC bits may be coupled in the eMBB individual payload 706, and/or in the eMBB encoded packet(s), including Symbol-k, Symbol-k=1, . . . , Symbol-N−1, Symbol-N in the example shown. The coupled bits can augment decoding of the eMBB packet(s). After URLLC decoding, the decoder may then either decode the eMBB packet(s), or decode the mMTC packet(s), including Symbol-the and Symbol-i+1 in the example shown. If the decoder attempts to decode the eMBB packet(s) after URLLC decoding and the eMBB decoding is successful, then the mMTC packet(s) can be decoded with lower error probability based on any coupled eMBB bits. Otherwise, if decoding of the mMTC packet(s) is attempted after URLLC decoding and are successfully decoded, then the eMBB packet(s) can be decoded with even lower probability based on any URLLC and/or mMTC bits coupled in the eMBB individual payload 706 or the eMBB packet(s). In the example shown in FIG. 7, the arrangement of encoded packets at 720 illustrates an embodiment that supports URLLC decoding, then mMTC decoding, and then eMBB decoding, but this is not the only possible decoding order.

Augmented decoding of a second packet, which may include one or more eMBB packets in the examples above, after the successful decoding of a first packet, which may include one or more URLLC packets and/or one or more mMTC packets in the examples above, is enabled by coupling of information bits and/or encoded bits between individual payloads and/or packets. In the case of coupled information bits, for example, a packet for which decoding is augmented will have been generated from fewer information bits of an individual payload, but the packet length remains the same, which results in a lower code rate. In the case of coupled code bits, a packet for which decoding is augmented will effectively have shortened code bits that are pre-known to the decoder, which also in effect results in a lower code rate. In both cases, whether information bits, coded bits, or both are coupled between packets, the code rate for augmented decoding, of eMBB packet(s) in the examples described with reference to FIG. 7, can be reduced. This can provide improved decoding performance by increasing the probability of successful decoding.

It should be noted that the packet(s) for which inter-packet coupling provides or supports augmented decoding may also be self-decodable. Coupling of bits between packets does not mean that augmented decoding must rely on prior successful decoding of coupled bits. For example, the eMBB packets(s) in the examples described with reference to FIG. 7 may be self-decodable regardless of whether decoding of the URLLC and/or mMTC packets was successful.

In an approach that may be referred to as HARQ-less uRLLC, one option is that if a self-decodable packet (say uRLLC) fails to decode, instead of requesting a retransmission, the receiver proceeds to decode another self-decodable packet (say eMBB). If the latter self-decodable code word is successfully decoded, the code rate of the former can be reduced, resulting in an improved performance. The other option is that if a self-decodable packet (say uRLLC) fails to decode, instead of requesting a retransmission, the receiver proceeds to jointly decode the entire code block including URLLC, eMBB and mMTC. If the joint code word is successfully decoded, all the bits can be correctly recovered.

The entire code block consists of URLLC, eMBB, and mMTC in FIG. 8 (discussed below), but this an illustrative and non-limiting example.

There are also two modes for coupling between URLLC symbols and eMBB symbols. The first is called tight coupling, where the coupling is within one slot or code block. The second is called loose coupling, where the coupling is between two consecutive slots or code blocks.

Tight coupling and loose coupling may be referred to using other names, and these are just examples of how different types, degrees, or strengths of couplings may be referenced.

FIG. 8 illustrates an example code block and encoded symbols. The code block 700 and encoded symbols 720 are the same as those shown in FIG. 7, but FIG. 8 illustrates different decoding at 800, as an example of HARQ-less URLLC. If a self-decodable packet (for URLLC for example) fails to decode, then instead of requesting a retransmission, the receiver may proceed to decode another self-decodable packet (for eMBB or mMTC, with mMTC being shown as an example in FIG. 8). If the latter self-decodable packet is successfully decoded, then the code rate of the former packet can be reduced based on coupled bits from the latter packet, resulting in improved performance. Another option is that if a self-decodable packet (for URLLC for example) fails to decode, then instead of requesting a retransmission, the receiver may proceed to jointly decode the entire joint codeword 720 to recover the entire code block 700. If the joint codeword 720 is successfully decoded, then all of the bits at 700 can be correctly recovered. In one example shown in FIG. 8 at 800, if both URLLC decoding and mMTC decoding fail, then joint decoding can still be successful.

Tight coupling within one time slot or one combined or joint code block 700 is shown in FIG. 8. To enable joint decoding, there is coupling between individual payloads or encoded blocks within one code block 700 or codeword 720. Tight coupling may be preferred, for example, because it enables joint decoding based on a single slot or parts of a single joint codeword rather than multiple slots or parts of multiple codewords.

In an approach that may be referred to as HARQ-less uRLLC with IR combining, only if the above second decoding attempts fail again, the receiver requests retransmission using incremental redundancy HARQ. The retransmission contains the incremental code bits for the first message (URLLC in this example), because a successful decoding of the first message will increase the chance of successful decoding for the subsequent messages. Optionally the retransmission may contain incremental code bits for the subsequent messages too, in order to further enhance decoding performance.

After receiving the retransmitted bits/symbols, the receiver will perform similar decoding attempts as mentioned above.

FIG. 9 illustrates another example code block and encoded symbols. The code block 700 and encoded symbols 720 are the same as those shown in FIGS. 7 and 8, but FIG. 9 illustrates different decoding at 900, as an example of HARQ-less URLLC with incremental redundancy (IR) combining. In some embodiments, there may be multiple decoding attempts without requesting retransmission, such as shown in FIGS. 7 and 8 above, and if those decoding attempts fail, then a receiver may request retransmission using incremental redundancy HARQ. This type of approach may still be referred to as “HARQ-less” in the context of the multiple decoding attempts before a first retransmission request is transmitted by a receiver and received by a transmitter, and HARQ-less URLLC with IR as referenced above adds the option of a retransmission request after multiple unsuccessful decoding attempts.

A retransmission preferably contains incremental redundancy information such as incremental code bits for the first message (URLLC in the example shown in FIG. 9), because successful decoding of the first message will increase the chance of successful decoding of subsequent messages. Optionally, the retransmission may also or instead contain incremental redundancy information such as incremental code bits for the subsequent messages, in order to further enhance decoding performance. IR decoding based on incremental codes bits is generally indicated at 900 by “IR Decode”, for both URLLC and mMTC in the example shown.

After receiving the retransmitted code bits, the receiver may perform similar decoding attempts as described by way of example above.

Regarding requests and retransmission, consider a conventional HARQ approach, which is enabled by ACK and/or NACK signaling, and up to four redundancy versions (RV1, RV2, RV3, RV4) for retransmission options. NACK signaling may be considered a form of retransmission request, in response to which a retransmission that includes a redundant version of previously transmitted data is sent by a transmitter. In this type of approach, a NACK would be sent by a receiver after a first decoding failure.

A second decoding attempt (“HARQ-less”) is made before retransmission is requested, via NACK signaling or otherwise. This may involve behaviors or features at either or both of an encoder/transmit device and a decoder/receive device.

In these NACK/NACK-2 examples, whether to request retransmission using NACK or NACK-2 is left for a decoder or receiving device to decide. A device can potentially send both NACK and NACK-2 after multiple decoding failures, or entirely skip the NACK for the first decoding failure and not send NACK at all. How to exploit the difference between NACK and NACK-2 is left for the transmit device to decide. It can prioritize retransmission for NACK-2 in the case of resource constraints, for example, or treat NACK and NACK-2 equally in the case of sufficient resources.

Retransmission procedures may also or instead be different. For example, in addition to, or instead of, redundant versions RV1 to RV4 in the conventional HARQ approach outlined above, there may be one or more new redundant versions or joint retransmission versions to indicate whether a retransmission is a standalone RV (as in the conventional example above), or embedded in an incoming payload or packet (for example, in an incoming eMBB packet to enable joint decoding of a URLLC packet or payload) through joint coding. This latter type of embedded retransmission may be referred to as a joint retransmission version or J-RV, for example, to enable a decoder or receive device to determine whether a retransmission is a standalone RV or a J-RV.

FIGS. 7 to 9, like other drawings herein, provide illustrative and non-limiting examples. Variations are possible. For example, individual payloads for different packets can be ordered according to any of various criteria, such as their priority or urgency. It may be preferable to decode individual payloads for more urgent services such as URLLC first, and accordingly those individual payloads may be at the beginning of a combined payload as shown. Code bits for those individual payloads will then be transmitted, received, and decoded before others.

Other criteria may also or instead be taken into account. For example, individual payloads and/or corresponding packets can be ordered according to data or packet size. Packets for smaller messages (fewer information bits) or fewer coded bits, for example, can be placed, transmitted, and received/decoded first. This may enable a smaller decoding LLR buffer because the first-received packets can be quickly decoded and the corresponding LLRs can then be flushed from the buffer.

There are several possible ways to do self- and joint-coding. In fact, the packets can be coupled in a chain structure, or coupled in a star structure.

Self- and joint-coding may include or involve self-decoding and joint-decoding, which may be provided or supported in any of various ways. Packets are referenced in the examples above, but more generally payloads or packets can be coupled according to a sequence or chain structure, or coupled in a star structure, for example.

The first way to do self- and joint-coding is called successive embedding. The encoding procedures are as follows:
Take K₁ information bits (for example, URLLC) and encode into N₁ code bits, the code rate is R₁=K₁/N₁
Take the K′₁ bits (from the K₁ bits, so K′₁≤K₁) and K₂ additional bits (for example, eMBB), K′₂=K′₁+K₂, and encode into N₂ code bits
   the code rate is R₂=K′₂/N₂>R₁
Take the K″₂ bits (from the K′₂ bits, so K″₂≤K′₂) and K₃ additional bits (for example, mMTC), K″₃=K″₂+K₃, and encode into N₃ code bits
   the code rate is R₃=K″₃/N₃>R₂
And so on: more payloads can be included in the above fashion.

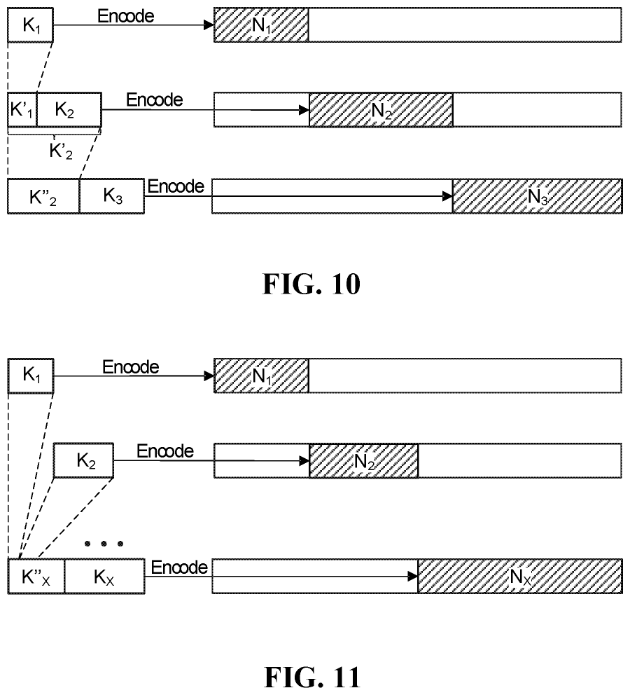

These encoding procedures are illustrated in FIG. 10.

FIG. 10 illustrates sequential coupling of bits between individual payloads, according to a sequence or chain structure. This type of encoding approach to provide or support self-decoding and joint-decoding may also or instead be referred to as successive embedding, to capture the notion that information bits from one individual payload are embedded or otherwise combined with information bits of another individual payload.

In the example shown in FIG. 10, K₁ information bits (associated with a URLLC service, for example) are encoded into N₁ code bits, for a code rate of R₁=K₁/N₁. Of the K₁ information bits, K′₁ bits (K′₁≤K₁) are prepended to K₂ additional bits of a different individual payload (for eMBB for example). Embedded bits may be prepended as shown, but in other embodiments embedded bits may be appended to or otherwise combined with information bits of a different individual payload. The combined K′₂=K′₁+K₂ bits are encoded into N₂ code bits, for a code rate of R₂=K′₂/N₂>R₁. K″₂ bits from the K′₂ (K″₂≤K′₂) are embedded, by prepending in the example shown, with K₃ additional bits from a different individual payload (for mMTC for example), and the resultant K″₃=K″₂+K₃ bits are encoded into N₃ code bits. The code rate is R₃=K″₃/N₃>R₂. A joint codeword includes the N₁ code bits, the N₂ code bits, and the N₃ code bits. This type of sequential or successive embedding may be repeated for more individual payloads, or in some embodiments there may be fewer than three individual payloads.

The second way to do self- and joint-coding is called multi-to-one embedding. The encoding procedures are as follows:
Take K₁ information bits (for example, URLLC) and encode into N₁ code bits, the code rate is R₁=K₁/N₁
Take K₂ information bits (for example, mMTC) and encode into N₂ code bits, the code rate is R₂=K₂/N₂
And so on: more payloads can be encoded into packets in the above fashion
Take the K′₁ bits (from the K₁ bits, so K′₁≤K₁), the K′₂ bits (from the K₂ bits, so K′₂ s K₂), and others to combine into K″ₓ bits. Gather the K″ₓ bits and the Kₓ additional bits (for example, eMBB) into K′ₓ=K″ₓ+Kₓ bits, and encode into Nₓ code bits
   the code rate is Rₓ=K′ₓ/Nₓ>R₁, Rₓ>R₂, and so on.

These encoding procedures are illustrated in FIG. 11.

FIG. 11 illustrates what may be referred to as multi-to-one coupling of bits between individual payloads, according to a star structure. This type of encoding approach to provide or support self-decoding and joint-decoding may also or instead be referred to as multi-to-one embedding, in which information bits from multiple different individual payloads are embedded or otherwise combined with information bits of one other individual payload.

In the example shown in FIG. 11, K₁ information bits (associated with a URLLC service, for example) are encoded into N₁ code bits for a code rate of R₁=K₁/N₁, and K₂ information bits (associated with an mMTC service, for example) are encoded into N₂ code bits for a code rate of R₂=K₂/N₂. This may be repeated if there are more than two individual payloads to be coupled to another individual payload. K′₁ bits of the K₁ information bits (K′₁≤K₁), K′₂ bits of the K₂ information bits (K′₂≤K₂), and some or all information bits of any other individual payloads that are to be coupled, are embedded with Kₓ additional bits of a different individual payload (for eMBB for example). Embedded bits may be prepended as shown, but in other embodiments embedded bits may be appended to or otherwise combined with information bits of a different individual payload. The combined K′ₓ=K″ₓ+Kₓ bits are encoded into Nₓ code bits, for a code rate of Rₓ=K′ₓ/Nₓ>R₁, Rₓ>R₂, and so on.

FIGS. 10 and 11 illustrate examples of coupling, in which one or more common bits couple one or more self-decodable encoded blocks with one or more other encoded blocks. In FIG. 10, common bits are successively embedded, between respective individual payloads that are encoded to generate a self-decodable encoded block (the K₁-bit block for example) and one or more other encoded blocks in a codeword, according to a sequence of the respective individual payloads in a combined payload corresponding to the codeword. In FIG. 11, the common bits are embedded, into one individual payload (at the bottom of FIG. 11 in the example shown) that is encoded to generate one encoded block, from respective individual payloads that are encoded to generate a self-decodable encoded block (the K₁-bit block for example) and another encoded block (the K₁-bit block for example).

These are examples only, and other types of coupling between individual payloads and/or encoded packets are possible, including a coupling approach that combines the sequential or successive coupling of FIG. 10 with the multi-to-one coupling of FIG. 11. For example, in such a mixed coupling approach, a first individual payload may be encoded according to sequential coupling and a second individual payload may be encoded according to multi-to-one coupling.

Coupling is not in any way limited to common bits between different individual payloads, and common bits may also or instead be common to encoded blocks. For example, in an approach similar to the example in FIG. 10 but applied to coded bits, common bits may be successively embedded between a self-decodable encoded block (the Nr-bit block for example) and one or more other encoded blocks according to a sequence of the self-decodable encoded block and the other encoded block(s) in a codeword. Similarly, considering multi-to-one coupling of encoded blocks, common bits may be embedded, into one encoded block (the Ne-bit block at the bottom of FIG. 11 for example) that is encoded to generate one encoded block, from the self-decodable block (the Nr-bit block for example) and one or more other encoded blocks (such as the N₂-bit block for example).

As another example, embedding may be applied between only some and not all individual payloads, and/or a combination of these two approaches may be applied.

Variations in encoding of information bits are also possible.

In encoding information bits in FIGS. 10 and 11, all information bits may be encoded using the same or similar types of codes, or different codes may be used for different individual payloads. This may also or instead be applied more generally to coding of individual payloads.

The above described procedure for mixed traffic coding may be also applicable to joint encoding of control and data information. However, in many scenarios, the control information and data information may be encoded by different coding types. For example, control information may be encoded by a Polar code, which is usually decoded using a hard-decision decoder while the data information may be encoded by a LDPC code, which can use a soft-in soft-out decoder. In some examples of this disclosure, a method for joint encoding of control and data to enhance control information reliability is described. Furthermore, the control channel may be also separately encoded and transmitted to maintain self decodability. A common example for the application of the joint encoding of control and data is to apply it to UCI and UL data (UL-SCH) multiplexing.

The present disclosure is not limited to polar and low density parity check (LDPC) codes. Soft-output iteratively decoded codes, for example, include convolutional codes, turbo codes, LDPC codes, product codes, and woven codes. Hard-output successively decoded codes include polar codes, polarization-adjusted convolutional (PAC) codes, Reed-Muller (RM) codes, Bose-Chaudhuri-Hocquenghem (BCH) codes, and Reed-Solomon (RS) codes.

In an example communication system, UCI can be multiplexed with UL-SCH on PUSCH channel. PUSCH refers to physical uplink shared channel, which is the physical channel that is mainly designed to transmit uplink data. PUCCH refers to physical uplink control channel, which is the main physical channel to transmit control information. UCI is the uplink control information. UL-SCH is the uplink shared channel, which is the transport channel that contains uplink data information. In this disclosure, UL-SCH can refer to uplink data information to be transmitted by the UE. NR supports multiple encoding chains of different UCI contents. Typical encoding chains on UCI may include:
1. HARQ-ACK (refers to the HARQ feedback information)
2. CSI-part I (CRI, RI, CQI 1st TB, and so on)
3. CSI-Part 2 (PMI, CQI 2nd TB, LI, and so on).

As described at least above, UL-SCH is the uplink shared channel, which is the transport channel that contains uplink data information. In some instances, UL-SCH is also used herein to refer to uplink data information to be transmitted by a UE. It should be readily apparent to a skilled person, from the context of each instance of UL-SCH, whether the channel or data is being referenced.

In one example, two different priorities (HP, LP) for UCI and UL-SCH are introduced when UCI is multiplexed with UL-SCH. In one example, UCI and UL-SCH are usually separately encoded, with UCI encoded by polar code (or small block code) while UL-SCH is encoded by LDPC code. Different multiplexing rules and rate matching are applied based on different UCI content and priority.

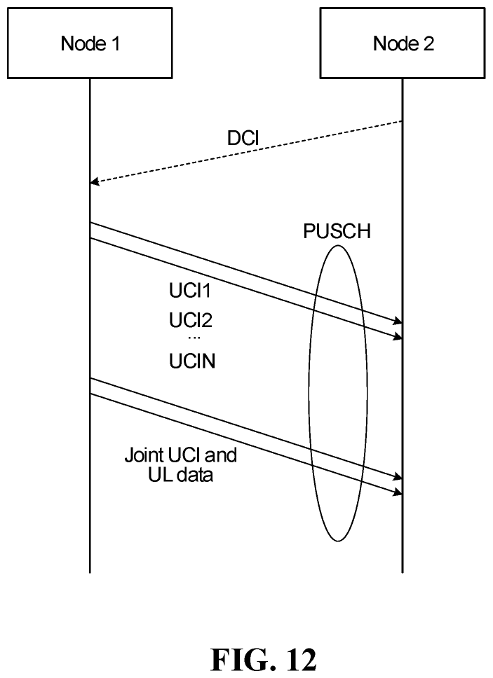

FIG. 12 shows a typical application scenario of the disclosure. In FIG. 12, Node 1 is usually a UE and Node 2 is a BS or network device, which can be gNB, eNB and so on, although Node 1 and Node 2 can be in general communication devices. In the communication procedure, Node 2 first may optionally send a message to schedule the uplink data transmission. The scheduling control message is usually sent in a DCI (for example in a dynamic grant), although it can also be sent in RRC or combination of RRC and DCI, for example in a configured grant transmission. Then, UE can send the uplink data transmission, which usually use the resource scheduled in the scheduling message. However, in the same time, the UE may need to send some other uplink control information in UCI, for example HARQ-ACK, CSI or combination of multiple UCI contents. The HARQ-ACK and CSI may be in response to some other transmission or request from BS. For example, HARQ-ACK is the HARQ feedback information, which is usually to indicate whether data transmission is successful or not in response to a previous downlink data transmission. CSI, which is the channel state information, may be triggered periodically or aperiodically by the BS. Instead of sending all the UCI in dedicated control channels, such as PUCCH, UE may choose to send UCI in PUSCH. If UE also have a UL data transmission, UE may send the UCI or multiple UCIs along with the UL data in the PUSCH resource, which is usually called multiplexing. Some of this disclosure describes a method to jointly encode UCI and PUSCH in the same coding chain to enhance UCI reliability instead of encoding UCI and UL data (UL-SCH) separately. There may still be separate UCI encoding chain transmitted as with the case of separate encoding. More details of the joint encoding scheme are described further in this disclosure.

For clarity, it is noted that the reference to FIG. 12 showing a typical application scenario of the disclosure is not an indication that embodiments disclosed herein are typical of currently known coding techniques. In this context a typical application is intended to refer to how embodiments disclosed herein would be expected to be applied. Similarly, regarding the reference to Node 1 being “usually” a UE, this is referring to the UL example shown, in which the transmitting node (Node 1 in FIG. 12) is usually a UE.

When UCI is multiplexed with UL-SCH in PUSCH, in some aspects of the present disclosure, a joint encoding method of UCI and UL-SCH for UCI reliability enhancement is proposed. For a joint encoding scheme, part of UCI information or coded bits may be embedded with UL-SCH data for encoding them together. While in the same time, there may still be separate encoding of UCI to make it self-decodable. There are several advantages of doing the joint encoding scheme: first, UCI payload is small, and joint encoding allows equivalently longer CB length for UCI, which can thus improve reliability. BS can decode UCI first and remove its effect from UL-SCH coding, and thus joint encoding has minimum to no impact on UL-SCH. Joint decoding complexity is low as Polar code is hard decision decoding and no outer iteration is needed.

Two UCI transmission and coding schemes are disclosed, with detailed designs. Scheme 1 is to enhance UCI decoding reliability with minimum impact on decoding performance of UL-SCH. Scheme 2 is a “HARQ-less” UCI scheme, which is aimed to achieve reliability of UCI content similar UCI repetition without additional resources and additional delay.

With the above two target schemes, the following embodiments of more specific solutions are proposed according to some aspects of this disclosure:
Example 1: All coded UCI bits embedded into UL-SCH, no additional UCI transmission
Example 2: Embed part of different coded bits from mother polar code (partial IR)
Example 3: Only part of high priority UCI information enhanced with UL-SCH coding
Example 4: Rate matching for UCI considers both coupled bits and original UCI coded bits.

Aspects of the present disclosure can jointly encode some of the UCI content with UL-SCH, while still maintaining self decodability of UCI by sending a separate encoded transmission for UCI. UCI can be a single UCI content (for example a HARQ-ACK) or joint encoding of multiple UCIs (for example a HARQ-ACK together with part 1 of a CSI). The multiple UCIs can potentially have different priorities (for example a HP-ACK together with a LP-ACK). The coupling UCI bits can be coded UCI bits or information bits. Since NR polar code for UCI is a non-systematic code, and the successive cancellation decoder uses soft input hard output, embedding coded bits can be beneficial to simplify decoding. For future generation wireless communications, the following UCI types may be supported
HARQ-ACK: used by UE to send HARQ feedback to the gNB or BS
CSI: channel state information, which is used to report channel quality to help BS select transmission parameters such as precoder and MCS
SR: scheduling request is used by UE to inform BS it has data to transfer and request BS to schedule a transmission for the UE
Sensing: UE may communicate with BS about sensing parameters or sensing results
CG-UCI/UTO-UCI: CG-UCI is configured grant UCI is used to accompany a configured grant transmission to inform BS about the parameters used in the configured grant transmission. The parameters can include HARQ process number, RV and so on. UTO-UCI is unused transmission opportunity UCI, which is used by UE to inform BS which configured grant resource is not used by the UE so BS can schedule the resource for other use.
Joint coding indication: There may be an indication sent in UCI from UE to BS to indicate to perform joint encoding between different traffic or between data and control channel like described in part of this disclosure
Other UCIs

More generally, any one or more of these UCI types may be supported in embodiments.

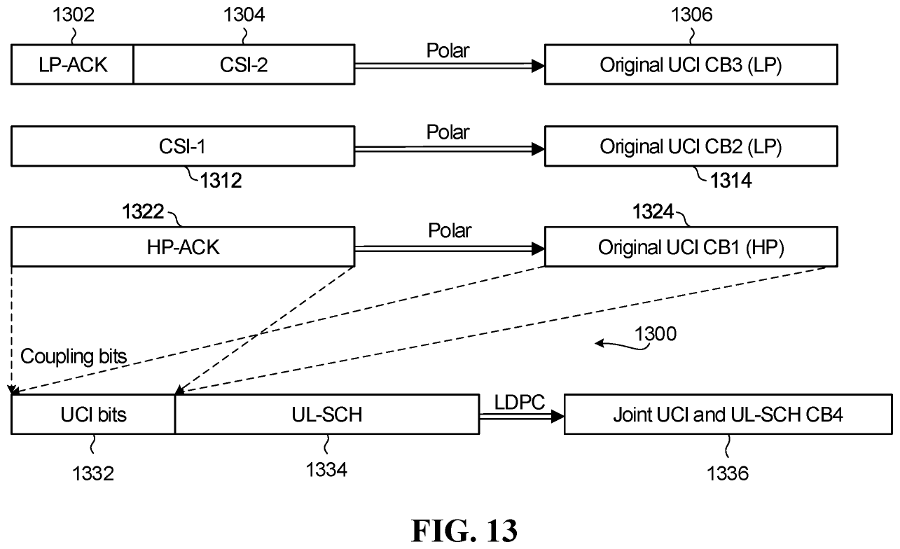

FIG. 13 shows an example of the joint UCI and UL-SCH coding scheme. In this scheme the original UCI content contains a high priority (HP) HARQ-ACK (for simplicity, referred to as HP-ACK in this disclosure) and a low priority (LP) HARQ-ACK (referred to as LP-ACK herein), a CSI information that is divided into part 1 of CSI and part 2 of CSI, it may have three code chains and three code blocks. The high priority (HP) ACK is encoded by polar code to produce code block 1 (CB1). The part 1 of CSI is encoded by a separate polar code to produce CB2. The information bits of low priority (LP) ACK and part 2 of CSI are bundled together and encoded by a polar code to produce CB3. Another information to be transmitted is the uplink data information that is the UL-SCH. In previous schemes, UL-SCH is separately encoded using a LDPC code.

In FIG. 13, the LP-ACK and part 2 of CSI (CSI-2) are shown at 1302, 1304, respectively. Part 1 of CSI (CSI-1) is shown at 1312, and the HP-ACK is shown at 1322. The three upper rows in FIG. 13 represent three code chains, which may also be referred to as encoding chains, each of which implements polar coding in the example shown. Encoding of the HP-ACK 1322 by polar code to produce CB1 at 1324 is shown in the third row, encoding of CSI-1 by a separate polar code to produce CB2 at 1314 is shown in the second row, and encoding of the information bits of the LP-ACK and CSI-2 by a polar code to produce CB3 at 1306 is shown in the first row. UCI bits 1332 are coupling bits, which may include HP-ACK bits from HP-ACK 1322 and/or coded HP-ACK bits from CB1 1324 as shown by the arrows at 1300, and joint encoding of the UCI bits 1332 and UL-SCH data 1334 by an LDPC code to generate CB4 at 1336 is shown in the bottom row of FIG. 13.

In one example of the proposed scheme, part or all of the HP-ACK bits can be embedded into UL-SCH and jointly encoded by LDPC code to produce CB4. The bits from the UCI that are embedded into UL-SCH for joint encoding are called coupling bits. The coupling bits from HP-ACK can be embedded as part of information bits along with original UL-SCH information bits as the new combined information bits and jointly encoded with LDPC codes. The coupling bits can be part or all of the information bits from the intended UCI (in this case HP-ACK), or can be polar coded bits of HP-ACK. The coupling bits can also be embedded in different location of the information bit sequence for jointly encoding with LDPC codes. For example, the coupling bits can be embedded at the beginning of the LDPC code information bits input sequence before the UL data input sequence. In another example, the coupling bits may be embedded into the beginning of the input sequence after the punctured bits in the LDPC codes to avoid the coupling bits being punctured, for example, in NR LDPC codes, the first 2Z, information bits are punctured, where Z, is the lifting size, then the coupling bits can be put after the first 2Z, bits of the data input sequence. In another example, the coupling bits may be put on high degree LDPC variable node such that it is generally more reliable among the information bits. In another example, the coupling bits may be put in the end of the information bits input sequences. In another example, the coupling bits may be put into beginning of the input sequence and interleaved before encoding, and the interleaver can be a pseudo random interleaver or other type of interleaver.

Some aspects of the present disclosure relate to embedding entire UCI coded bits.

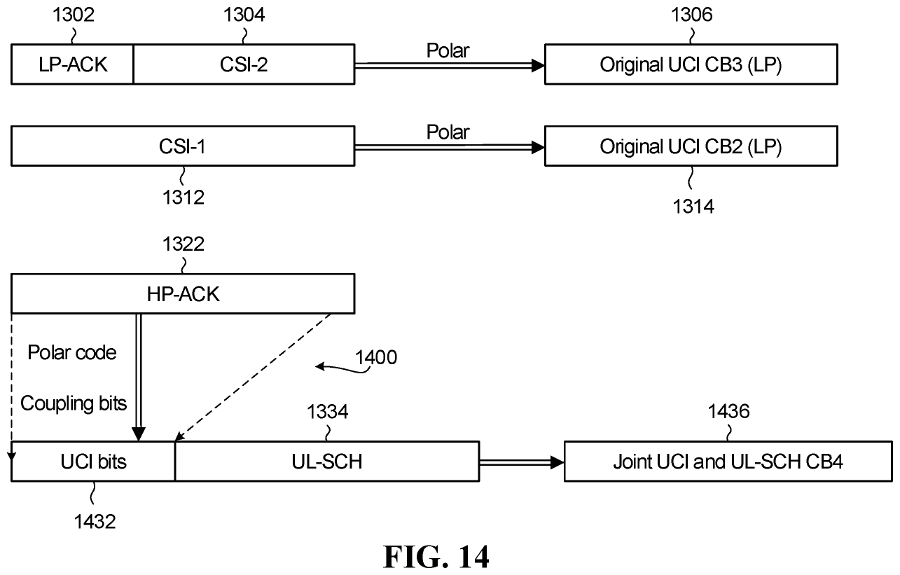

FIG. 14 describes an example of embedding entire UCI coded bits into UL data for joint encoding. With this method, the UCI is first encoded by a polar code (or other code for UCI encoding) and all the coded bits are embedded into UL data as input information bits and jointly encoded by a LDPC code. After embedding coded UCI bits, additional separate UCI code chain for the same UCI may not be transmitted, which simplify the encoding and resource mapping process. In the figure, HP-ACK is encoded by polar code and the entire coded bits are used a coupling bit to be embedded as part of information bits together with UL data. The combined information bits from HP-ACK coded bits and original UL-SCH information bits are jointly encoded by an LDPC code to produce joint UCI and UL-SCH coded bits. In this example, there may not be a separate HP-ACK code chain transmitted separately.

In FIG. 14, the encoding chains in the first two rows are the same as in FIG. 13. The UCI in the example shown is the HP-ACK 1322. Polar coding of the HP-ACK 1322 is shown by way of example by the double arrow at 1400, and embedding of all of the polar coded bits into UL data 1334 is shown by the single arrows at 1400. No CB1 is shown in FIG. 14 to illustrate that there may be no separate coding of the HP-ACK 1322 in some embodiments. A CB4 is shown at 1436, which is generated by encoding (by an LDPC code as in FIG. 13, for example) the UL data 1334 and embedded HP-ACK coded bits 1432. Even without a separate coding chain of the HP-ACK 1322, the HP-ACK can be potentially decoded by the coupling bits, that are transmitted as part of the systematic bits in CB4 in the example shown, alone. However, the joint encoding of CB4 can greatly improve the chance of decoding the HP-ACK 1322.

To decode the UCI and UL-SCH data, one can first try to decode the joint encoded LDPC codes, if it is successfully decoded, both UCI and UL-SCH will be decoded successfully. If not, the decoder output can still produce soft information (for example extrinsic LLR) for the UCI coded bits to help with UCI (HP-ACK in this example) decoding. The UCI use the transmitted UCI coded bits, which is part of the systematic bits from LDPC code output, together with the soft information from LDPC decoder, to decode the UCI. The transmitted UCI coded bits produce channel LLR, which can be combined with extrinsic LLR from LDPC decoder, together it provides two level protection for HP-ACK. After decoding HP-ACK successfully, its impact can be removed from the LDPC code for UL-SCH coding, which further improves the UL-SCH LDPC decoding performance. The UCI that is used for coupling can be one high priority UCI content (for example one HP-ACK as in this example) or combine multiple UCI contents. The rest of the UCI contents which includes part 1 of CSI, a combination of part 2 of CSI and LP-ACK, may be encoded by Polar codes into separate code chains, respectively, as shown in FIG. 14.

Some aspects of the present disclosure relate to embedding different part of mother code coded bits.

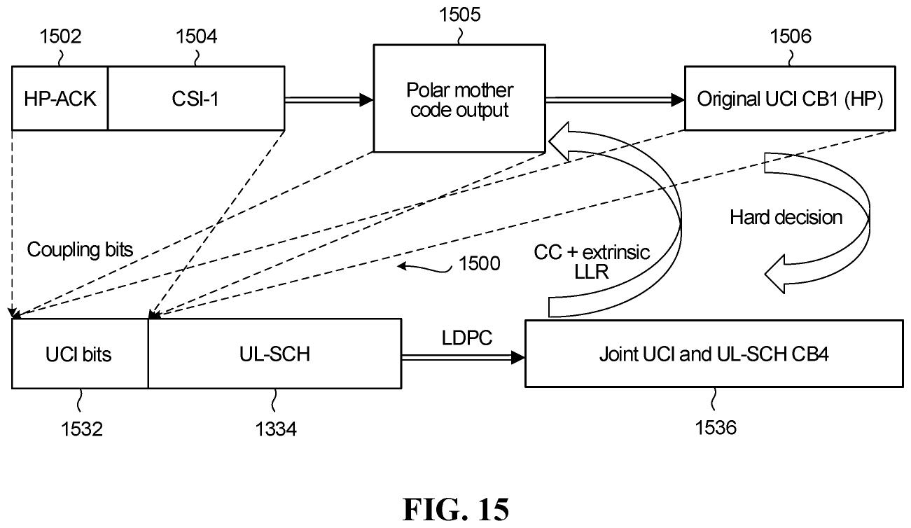

FIG. 15 shows an example of embedding different part of coded bits from UCI with UL-SCH for joint encoding. The embedded bits (or coupling bits) can be UCI information bits or coded bits from the UCI encoding chain. For the original UCI code chain, the information bits are usually encoded first using a Polar code with a specific code length, which are usually called mother code, to produce a set of coded bits encoded from the mother code, then the actual output coded bits are selected from set of coded bits from output of mother code, this process is usually called rate matching. As in the example shown in FIG. 15, HP-ACK and part 1 of CSI is first encoded by a Polar mother code with a specific mother code length M, which is usually equal to 2ⁿ, where n is an integer, for example 512 or 1024, then rate matching (RM) process is used to select the original UCI coded bits output from M coded bits from mother code, which ensures a specific target code rate is achieved. When coded bits are used for coupling, the coded bits can be selected from part of the original coded bits for UCI code chain (the coded bits for CB1 in this example) (this may be considered a chase combining (CC) scheme) or different coded bits (but may overlap with part of the coded bits for UCI transmission) select from the mother code of the original Polar codes (this may be considered a partial IR scheme).

In FIG. 15, the UCI encoding chain illustrated at the top row encodes the HP-ACK 1502 and CSI-1 1504 by a polar mother code to generate the polar mother code output (before rate matching) 1505. The arrows at 1500 are intended to illustrate that the embedded bits (or coupling bits) 1532 for CB4 at 1536 can be UCI information bits and/or coded bits from the UCI encoding chain, and when coded bits are used for coupling, coded bits can be selected as coupling bits from part of the original coded bits for the UCI code chain (the coded bits for CB1 1506 in this example) and/or from the mother code output 1505.

For a partial IR scheme, in one example, the code bits may be selected from the beginning or ending of the mother code output. The method for selection of coded bits among the mother code output depend on original rate matching (RM) scheme
For example, if the original RM for the UCI Polar code is based on puncturing, for example puncturing the beginning of mother code output, pick the coupling bits from the beginning of the mother code output
If original RM method for the UCI Polar code is based on shortening, pick the coupling bits from the end of the mother code output
If original RM method for the UCI Polar code is based on repetition, pick the coupling bits from the bits that are not repeated

If some coded bits depend only on some frozen information bits, then those bits should be avoided during selection of the coupling bits. In some example, the embedded coupling bits can be punctured in the output of the encoded bits if minimum impact on UL-SCH is desirable. This is because the coupling bits either have already been transmitted in the UCI transmission or it is with high reliability due to the UCI transmission, thus puncturing it allows more other coded bits to be transmitted for improving the UL-SCH decoding performance of the LDPC code.

Some aspects of the present disclosure relate to partial high priority UCI coupling.

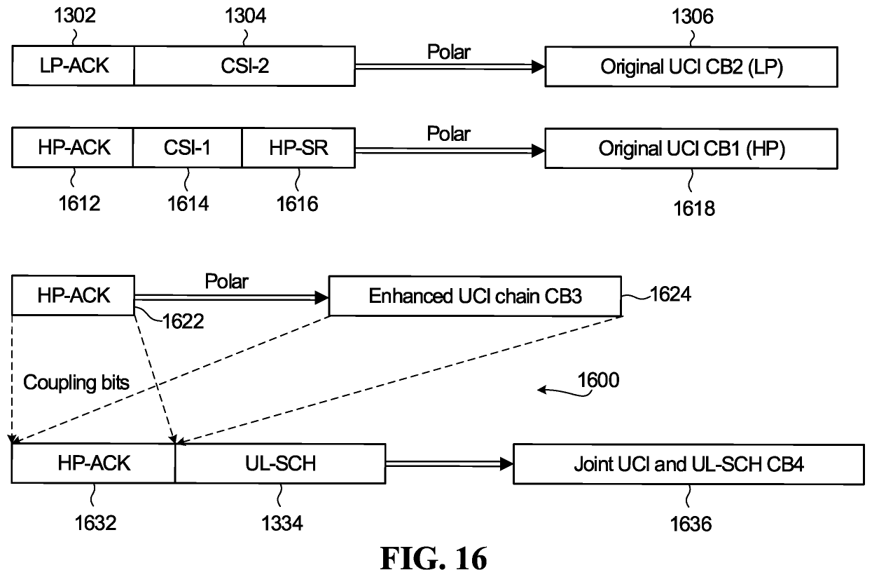

The coupling bits can be only part of the High reliability UCI content (for example HP-ACK) instead of all UCI content in one of the existing UCI code chains. For example, in the example of FIG. 16, only the HP-ACK UCI is coupled with UL-SCH for joint encoding using LDPC codes. Coupling bits can be coded bits or information bits. In the example, HP-ACK may be protected multiple times in CB1, CB3 and CB4, which may reduce the needs of repetition for high reliability requirements. In CB3 HP-ACK is encoded separately using its own coding chain. In CB1, it is jointly encoded by Polar codes with other UCI information (part 1 of CSI and SR in the example). In CB4, it is protected together with UL-SCH by an LDPC code.

In FIG. 16, encoding of the LP-ACK 1302 and CSI-2 1304 by a polar code to generate CB2 at 1306 may be the same as in FIG. 13. Encoding by a polar code as illustrated in the second row of FIG. 16 may be substantially the same as in FIG. 13 as well, except that HP-ACK 1612, CSI-11614, and HP-SR 1616 are encoded to generate CB1 at 1618. HP-ACK is also shown at 1622 in FIG. 16, to illustrate separate encoding of the HP-ACK by a polar code to generate CB3 at 1624. The “Enhanced” label at 1624 is intended to indicate that although HP-ACK is already jointly encoded in CB1, separate encoding of HP-ACK UCI is added to help further protect the high priority HP-ACK. Coupling bits associated with the HP-ACK are shown at 1632, and are coupled with UL-SCH data 1334 for joint encoding, using an LDPC code for example, to generate CB4 at 1636. The arrows at 1600 illustrate that the coupling bits 1632 can include coded bits from CB3 1624 and/or information bits from the HP-ACK 1622.

Some aspects of the present disclosure relate to rate matching of polar codes.

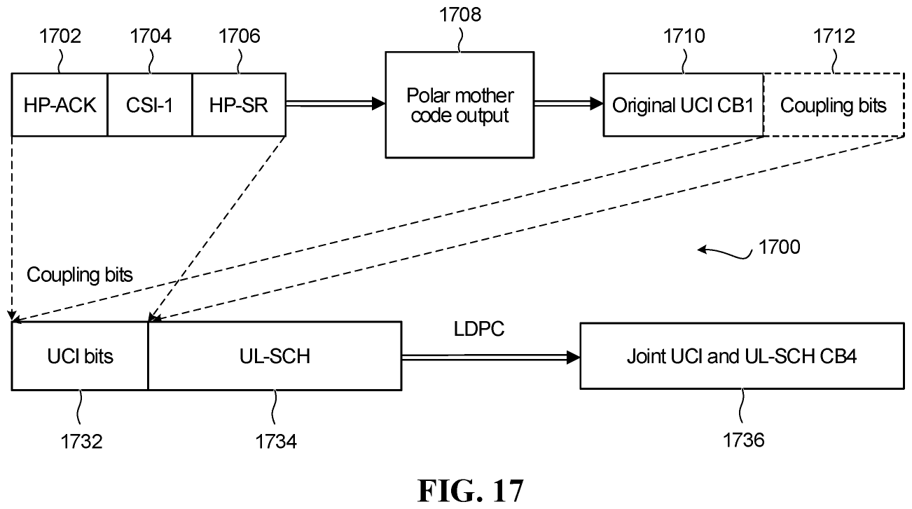

FIG. 17 shows another example of the joint UCI and UL data encoding scheme. In some examples of the disclosure, the mother code selection and rate matching for the UCI may take into account the coupling bits. That is, when doing UCI rate matching and determining mother code, code length of both UCI coded bits and coupling bits may be considered.

As Polar code mother code length may depend on the code rate of the Polar code, for example, the code length (number of coded bits output from mother code) can be 512 or 1024 depending on how many coded bits needed in the output coded bits of CB1. In some examples of the joint UCI and UL-SCH encoding scheme, the code length of Polar code mother code may be obtained based on both the original UCI coded bits and the coupling bits, that is, the equivalent number of UCI coded bits that combines both the original UCI coded bits in CB1 and coupling bits. Similarly, the rate matching scheme for selection of the UCI output coded bits from the Polar code mother code also depends on the combination of the original UCI coded bits and the coupling bits. After obtaining the combination of the original UCI coded bits in CB1 and the coupling bits, part of the combined coded bits are used for coupling bits and the rest are used for the original UCI transmission in CB1 as shown in the example.

In FIG. 17, encoding of the HP-ACK 1702, CSI-11704, and HP-SR 1706 by a polar mother code to generate the polar mother code output at 1708 is shown in the top row. The top row in FIG. 17 also illustrates CB1 for transmission at 1710, and the coupling bits 1712, which in this example are selected from the polar mother code output at 1708 but are not transmitted in CB1. In FIG. 17, the original UCI coded bits in CB1 at 1710 and the coupling bits 1712 may also be generated and selected together from Polar mother code output 1710 based on the rate matching scheme of Polar code, and the coupling bits are embedded with the UL-SCH data and encoded using the LDPC code in CB4 at 1736, while the rest of the UCI coded bits at 1710 may be transmitted as CB1. The arrows at 1700 in FIG. 17 are intended to illustrate that the coupling bits in the UCI bits 1732, which are embedded with the UL-SCH data 1734, may include UCI bits from one or more of the HP-ACK 1702, CSI-11704, or HP-SR 1706, and/or coded bits shown as the coupling bits 1712.

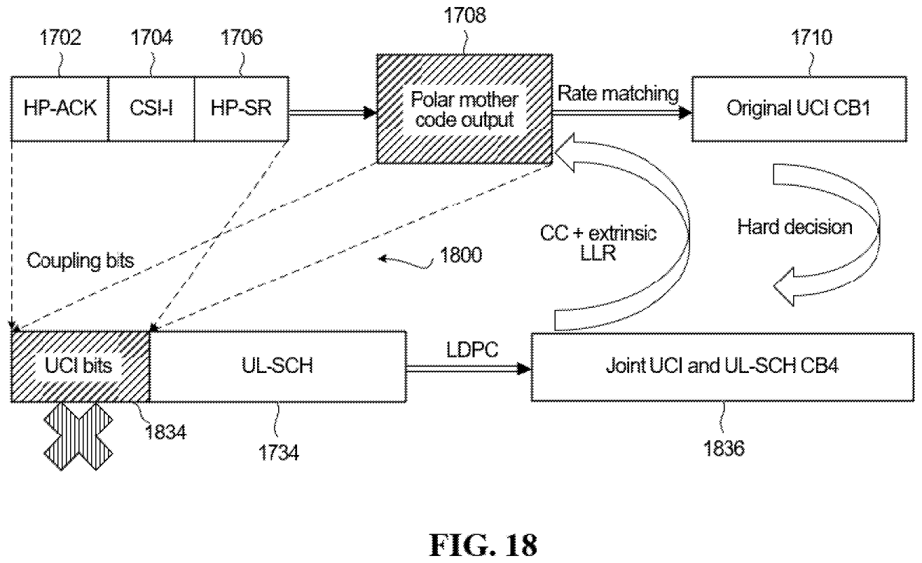

FIG. 18 shows an example of the decoding. The example is in a scenario similar to the example in FIG. 17. The coupling bits are selected from part of the Polar code mother code output, which can be different or partially different than the original UCI coded bits in CB1. The coupling bits may be punctured or not punctured in the LDPC code output in CB4. As described before, the decoding may be done in
Step 1 (optional): Combine channel LLR of the UCI coded bits and attempt to decode the polar code (The step is performed if minimum latency for UCI is needed as it can be decoded before receiving the UL-SCH information)
Step 2: If the UCI coupling bits have been decoded from Polar decoder, assign large LLR as the corresponding coupling bits in the LDPC codes that used for joint UCI and UL-SCH coding, try to decode the LDPC code in CB4.
Step 3: Send the extrinsic LLR of UCI coupling bits from LDPC decoder to the polar decoder, the polar code decoder combines the extrinsic LLR with channel LLR determined based on received signal of the coupling bits as the reliability input for the polar code and attempt to decode polar code again.
Step 4: If Polar code decode successful, take the decoder output as UCI decoding results, repeat Step 2 (decode stop if Polar code decoding fails, no outer iteration). Take the LDPC decoder output from Step 2 for the UL-SCH decoding results.

In FIG. 18, Step 3 is illustrated as “CC+extrinsic LLR”. Here, CC refers to chase combining. There may be coupling bits sent in both original UCI code chain CB1 1710 as well as in CB4 1836 as part of the systematic bits, and accordingly the channel LLR for both transmissions of the same coded bits may be first combined, and then extrinsic LLR for coupling bits produced from output of the LDPC code in CB4 are added on top to obtain the input LLR for the coupling bits as part of the input for the Polar code decoder in CB1. Taking the decoder output as UCI decoding results in Step 2 and Step 4 is illustrated as “Hard decision”. Once the polar code in CB1 1710 is decoded successfully, the coupling bits become known bits, and then large LLR values can be assigned as input LLR of the coupling bits for the LDPC decoding of CB4 1836. Most of the reference numbers in FIG. 18 are as shown in FIG. 17, with the exception of 1800 where the arrows illustrate possible selection of coupling bits from the polar mother code output 1708 (and the coupling bits may include coded bits in CB1 and/or coded bits in the polar mother code output that are not in CB1), 1834 where again the coupling bits may include coded bits in CB1 and coded bits in the polar mother code output that are not in CB1, and 1836 where CB4 is generated by coupling bits that are embedded with the UL-SCH bits 1734 and may include coded bits in CB1 and/or coded bits in the polar mother code output that are not in CB1. The “X” symbol below the UCI bits 1834 in FIG. 18 illustrates possible puncturing of the UCI bits in LDPC code output bits.

Some aspects of the present disclosure relate to rate matching and resource multiplexing.

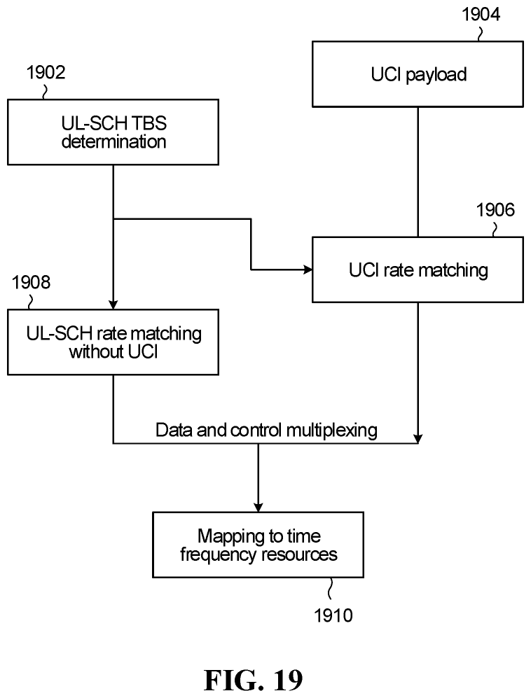

FIG. 19 shows a general procedure for determining UCI and UL-SCH coding parameters and resource multiplexing scheme.

In the first step, the transport block size (TBS) for the uplink data is first determined.

This is illustrated at 1902 in FIG. 19.

Regarding UL-SCH TBS determination, an example of the procedure to determine the payload size of the UL data (UL-SCH), which is the procedure of determining the transport block size (number of the information bits for the transport block) of PUSCH in current NR standard ([3GPP TS 38.214 version 17.5.0 Section 6.1.4]), is as follows:

The UE shall first determine the number of REs (N_{RE}) within the slot:
A UE first determines the number of REs allocated for PUSCH within a PRB

$$( {N}_{RE}^{′} )$$

by

$${N}_{RE}^{′} = {N}_{sc}^{RB} \cdot {N}_{symb}^{sh} - {N}_{DMRS}^{PRB} - {N}_{oh}^{PRB} , where {N}_{sc}^{RB} = 12$$

is the number of subcarriers in the frequency domain in a physical resource block,

$${N}_{symb}^{sh}$$

is the number of symbols L of the PUSCH allocation according to Clause 6.1.2.1 of [3GPP TS 38.214] for scheduled PUSCH or Clause 6.1.2.3 [3GPP TS 38.214] for configured PUSCH,

$${N}_{DMRS}^{PRB}$$

is the number of REs for DM-RS per PRB in the allocated duration including the overhead of the DM-RS CDM groups without data, as described for PUSCH with a configured grant in Clause 6.1.2.3 of [3GPP TS 38.214] or as indicated by DCI format 0_1 or DCI format 0_2 or as described for DCI format 0_0 in Clause 6.2.2 [3GPP TS 38.214], and

$${N}_{oh}^{PRB}$$

is the overhead configured by higher layer parameter xOverhead in PUSCH-ServingCellConfig. If the

$${N}_{oh}^{PRB}$$

is not configured (a value from 6, 12, or 18), the

$${N}_{oh}^{PRB}$$

is assumed to be 0. In case of PUSCH repetition Type B,

$${N}_{DMRS}^{PRB}$$

is determined assuming a nominal repetition with the duration of L symbols without segmentation.
A UE determines the total number of REs allocated for PUSCH (N_{RE}) as follows
   For TB processing over multiple slots,

$${N}_{R E} = N * min ( 1 \; 56 , {N}_{R E}^{′} ) \cdot {n}_{P R B}$$

where n_{PRB} is the total number of allocated PRBs for the UE and N is the number of slots used for TBS determination indicated by numberOfSlotsTBoMS.
Otherwise,

$${N}_{R E} = min ( 1 \; 56 , {N}_{R E}^{′} ) \cdot {n}_{P R B} .$$

Next, proceed with the following steps 2) to 4):
2) Unquantized intermediate variable (N_{info}) obtained by N_{info}=N_{RB}·RQₘv,
   Where R is the target code rate and Qₘ is the modulation order (the number of bits per modulated symbol), which are indicated in the MCS index in DCI and obtained from mapping the MCS index in the MCS table. v is the number of layers (or MIMO layers) for the transmission.

```
If N_{inf o} ≤ 3824
  Use step 3 as the next step of the TBS determination
else
  Use step 4 as the next step of the TBS determination
end if
```

3) When N_{info}≤3824, TBS is determined as follows
   quantized intermediate number of information bits

$${N}_{inf o}^{′} = max ( {24.2}^{n} \cdot ⌊ \frac{{N}_{inf o}}{{26}^{n}} ⌋ ) ,$$

where n max(3,└log₂(N_{info})┘−6).
use Table 5.1.3.2-1 find the closest TBS that is not less than N_{info}.

TABLE 5.1.3.2-1
TBS for N_{info} ≤ 3824

| Index | TBS |
|---|---|
| 1 | 24 |
| 2 | 32 |
| 3 | 40 |
| 4 | 48 |
| 5 | 56 |
| 6 | 64 |
| 7 | 72 |
| 8 | 80 |
| 9 | 88 |
| 10 | 96 |
| 11 | 104 |
| 12 | 112 |
| 13 | 120 |
| 14 | 128 |
| 15 | 136 |
| 16 | 144 |
| 17 | 152 |
| 18 | 160 |
| 19 | 168 |
| 20 | 176 |
| 21 | 184 |
| 22 | 192 |
| 23 | 208 |
| 24 | 224 |
| 25 | 240 |
| 26 | 256 |
| 27 | 272 |
| 28 | 288 |
| 29 | 304 |
| 30 | 320 |
| 31 | 336 |
| 32 | 352 |
| 33 | 368 |
| 34 | 384 |
| 35 | 408 |
| 36 | 432 |
| 37 | 456 |
| 38 | 480 |
| 39 | 504 |
| 40 | 528 |
| 41 | 552 |
| 42 | 576 |
| 43 | 608 |
| 44 | 640 |
| 45 | 672 |
| 46 | 704 |
| 47 | 736 |
| 48 | 768 |
| 49 | 808 |
| 50 | 848 |
| 51 | 888 |
| 52 | 928 |
| 53 | 984 |
| 54 | 1032 |
| 55 | 1064 |
| 56 | 1128 |
| 57 | 1160 |
| 58 | 1192 |
| 59 | 1224 |
| 60 | 1256 |
| 61 | 1288 |
| 62 | 1320 |
| 63 | 1352 |
| 64 | 1416 |
| 65 | 1480 |
| 66 | 1544 |
| 67 | 1608 |
| 68 | 1672 |
| 69 | 1736 |
| 70 | 1800 |
| 71 | 1864 |
| 72 | 1928 |
| 73 | 2024 |
| 74 | 2088 |
| 75 | 2152 |
| 76 | 2216 |
| 77 | 2280 |
| 78 | 2408 |
| 79 | 2472 |
| 80 | 2536 |
| 81 | 2600 |
| 82 | 2664 |
| 83 | 2728 |
| 84 | 2792 |
| 85 | 2856 |
| 86 | 2976 |
| 87 | 3104 |
| 88 | 3240 |
| 89 | 3368 |
| 90 | 3496 |
| 91 | 3624 |
| 92 | 3752 |
| 93 | 3824 |

```
    When N_{info} > 3824, TBS is determined as follows.
  - quantized intermediate number of information bits
    ${N}_{info}^{′} = max ( 3840 , {2}^{n} \times round ( \frac{{N}_{info} - 24}{{2}^{n}} ) ) , where$
    n = └log₂(N_{info} − 24)┘ − 5 and ties in the round function are broken
    towards the next largest integer.
  - if R ≤ 1/4
    $TBS = 8 \cdot C \cdot ⌈ \frac{{N}_{info}^{′} + 24}{8 \cdot C} ⌉ - 24 , where C = ⌈ \frac{{N}_{info}^{′} + 24}{3816} ⌉$
  else
    $if {N}_{info}^{′} > 8424$
      $TBS = 8 \cdot C \cdot ⌈ \frac{{N}_{info}^{′} + 24}{8 \cdot C} ⌉ - 24 , where C = ⌈ \frac{{N}_{info}^{′} + 24}{8424} ⌉$
    else
      $TBS = 8 \cdot ⌈ \frac{{N}_{info}^{′} + 24}{8} ⌉ - 24$
    end if
  end if
```

In some examples of this disclosure, TBS determinations may be determined by taking into account the UCI resources, which can result in less impact on the code rate of UL-SCH (to make it closer to the target code rate). In this scenario, TBS may be determined based on removing UCI resource, that is, the number of resource elements allocated for UL data (UL-SCH), which is obtained by the REs allocated for all the PUSCH resources minus the REs allocated for UCI:

$${N}_{R E} ( UL - SCH ) = {N}_{R {E}^{-}} {N}_{R E} ( UCI )$$

N_{RE}(UL-SCH) is used instead of the original N_{RE} to calculate TBS.

In another example, TBS is unchanged and based on REs allocated for all PUSCH without removing REs allocated for UCI.

After determining TBS, in one example, the UL-SCH payload size may be obtained by removing the size of UCI coupling bits from TBS. In another example, the UL-SCH payload size may be obtained directly from TBS without removing the size of UCI coupling bits.

A next step may involve determining UCI payload and UCI rate matching. This step may include determining the UCI payload as shown at 1904, and then UCI rate matching as shown at 1906. Unlike the UL-SCH data, where the payload or TBS is determined based on the available resource and target MCS, the UCI payload size may be given or determined based on the UCI content that is to be transmitted. For example, if the UCI is a HARQ-ACK, and the HARQ-ACK includes 2 bits that are used to transmit 2 HARQ feedback for 2 TBs with 1 bit each, then the UCI payload is 2 bits. In another example, if the UCI is a CSI report, then the number of bits for the CSI may also be determined based on how many bits are to be reported from this particular CSI format. The UCI rate matching process is determined based on the given UCI payload.

Some aspects of the present disclosure relate to UCI rate matching.

For the UCI rate matching, in some embodiments, the number of coded symbols calculated from the UCI resources may include both the UCI coded bits and the coupling bits.

In FIG. 19, a UCI payload is shown at 1904, and UCI rate matching is shown at 1906.

For example, the number of coded symbols for a HARQ-ACK and part 1 of CSI that is transmitted in a PUSCH may be given by different beta offset as shown in the two equations below, which is similar to UCI rate matching scheme in [3GPP TS 38.212 V17.5.0 Section 6.3.2.4.1], where

$${Q}_{ACK}^{′} and {Q}_{CSI - 1}^{′}$$

are the number of coded modulation symbols per layer for transmission of HARQ-ACK UCI and part 1 of CSI, respectively.

$${β}_{offset}^{PUSCH}$$

is the beta offset assigned for the UCI, which represents a ratio of resource UCI can occupy on the PUSCH resources.

In the equations below,
O_{ACK} is the number of HARQ-ACK bits;
L_{ACK} is the number of CRC bits for HARQ-ACK;
C_{UL-SCH} is the number of code blocks for UL-SCH of the PUSCH transmission;
Kᵣ is the r-th code block size for UL-SCH of the PUSCH transmission;

$${M}_{SC}^{UCI} ( l )$$

is the number of resource elements that can be used for transmission of UCI in OFDM symbol l, for

$$l = 0 , 1 , 2 , … , {N}_{symb , {all}_{- 1}}^{PUSCH} ,$$

in the PUSCH transmission and

$${N}_{symb , all}^{PUSCH}$$

is the total number of OFDM symbols of the PUSCH, including all OFDM symbols used for DMRS;
α is configured by higher layer parameter scaling;
l₀ is the symbol index of the first OFDM symbol that does not carry DMRS of the PUSCH, after the first DMRS symbol(s), in the PUSCH transmission.

$${Q}_{CSI - 1}^{′}$$

is calculated similarly. More detailed description on calculation of the number of coded symbol for each UCI can be found in [3GPP TS 38.212 V17.5.0 Section 6.3.2.4.1].

$${Q}_{ACK}^{′} = min \{ ⌈ \frac{( {O}_{ACK}^{} + {L}_{ACK}^{} ) \cdot {β}_{offset}^{PUSCH} \cdot {\sum }_{l = 0}^{{N}_{symb , all}^{PUSCH} - 1} {M}_{sc}^{UCI} ( l )}{{\sum }_{r = 0}^{{C}_{UL - SCH} - 1} {K}_{r}} ⌉ , ⌈ α \cdot {\sum }_{l = {l}_{0}}^{{N}_{symb , all}^{PUSCH} - 1} {M}_{sc}^{UCI} ( l ) ⌉ \} \\ {Q}_{CSI - 1}^{′} = min \{ ⌈ \frac{( {O}_{CSI - 1}^{} + {L}_{CSI - 1}^{} ) \cdot {β}_{offset}^{PUSCH} \cdot {\sum }_{i = 0}^{{N}_{symb , all}^{PUSCH} - 1} {M}_{sc}^{UCI} ( l )}{{\sum }_{r = 0}^{{C}_{UL - SCH} - 1} {K}_{r}} ⌉ , ⌈ α \cdot {\sum }_{l = 0}^{{N}_{symb , all}^{PUSCH} - 1} {M}_{sc}^{UCI} ( l ) ⌉ - {Q}_{ACK / CG - UCI}^{′} \}$$

Resource is given priorities to high priority UCI. However, in some example of this disclosure, this number of coded symbols calculated using UCI resources can represent the sum of UCI coded bits and coupling bits for the joint UCI and UL-SCH decoding scheme instead of UCI coded bits alone. In the case when the number of coded symbols for UCI calculated here does not include additional coupling bits, for example, it can be directly used for generating the number of coded symbols for resource multiplexing and transmission of the UCI code, for example,

$${Q}_{ACK}^{′}$$

number of coded symbols for HARQ-ACK will be generated and used for resource mapping and transmission for HARQ-ACK. In the case where the number of coded symbols for UCI calculated includes additional coupling bits, for example

$${Q}_{ACK}^{′} ,$$

then the number of coupling bits should be removed, that is, the number of actual coded symbols generated for the HARQ-ACK code chain for resource mapping and transmission is given by

$${Q}_{ACK}^{′}$$

−number of coupling symbols, where number of coupling symbols is the number of coupling bits divided by the modulation order. The additional number of coupling bits may be generated from the HARQ-ACK code chain for use in embedding into the UL-SCH code chain for joint encoding.

A next step in some embodiments is UL-SCH rate matching. This step is to determine the coded bits to be selected in the encoding output. After the UL-SCH TBS determination in 1902, the payload of UL-SCH data and embedded coupling bits from UCI are put together for encoding. There are common encoding steps for UL-SCH data before rate matching that may not be shown in FIG. 19 before 1908, which may include TB CRC attachment, CB segmentation, encoding, and so on, before the rate matching process. The number of coded bits is determined based on the available REs to transmit the encoded UL-SCH in the PUSCH resources as determined in the TBS determination process at 1902. In some examples, this UL-SCH rate matching process is determined without considering the situation that UCI is multiplexed on the same resource. In this situation, the number of coded bits that are actually transmitted are reduced due to UCI through the process of data and control multiplexing when mapping to the time and frequency resource. In FIG. 19, the UL-SCH rate matching process is shown at 1908, and the label “without UCI” refers to the example where the number of coded bits selected for the rate matching process does not consider the resources occupied by the UCI. In some other examples, the UL-SCH rate matching process may consider that UCI occupies resources when selecting coded bits from the encoding output for UL-SCH data. For example, the number of coded bits selected from encoding output may be determined based on available REs that is calculated after removing the UCI resources, similar to the example of TBS determination considering UCI resources.

A next step may be called data and control multiplexing, which determines how to map the coded symbols for UL-SCH data and coded symbols for UCI into the time and frequency resources allocated for PUSCH.

Some aspects of the present disclosure relate to data and control multiplexing.

In FIG. 19, mapping of coded symbols to time frequency resources is shown at 1910.

Mapping the UCI and UL-SCH coded symbols into time frequency resources (REs) may follow a predefined order and rule. In one example, some of the UCI bits, for example HARQ-ACK bits are mapped to fixed reserved allocation. Then the rest of the UCI bits, such as part 1 of CSI is mapped to the time frequency grid. After that, part 2 of CSI may be mapped. Afterwards, the coded symbols for UL-SCH may be mapped in the remaining resources afterwards by rate matching the existing UCI symbols. All mapping may avoid some reference signals location, such as DMRS.

In some examples of the joint encoding scheme described in this disclosure, joint encoding of UCI and UL-SCH is treated as UL-SCH for multiplexing rule.

In some examples, the systematic coupling bits that is coming from UCI may be mapped separately from the rest of the UL-SCH coded symbols. The coded symbols of these coupling bits may be treated as part of UCI encoding chain and mapped to UCI resource first for better reliability. In some other examples, the coupling bits may be considered part of the UL-SCH coded symbols and following the mapping rules of UL-SCH.

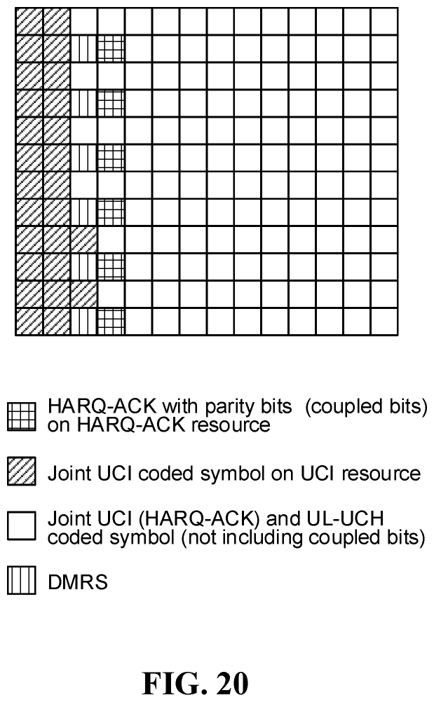

FIG. 20 illustrates a resource mapping example, where the overall time frequency resources are shown in a time frequency grid. Each rectangle in the time frequency grid represents an RE or a time frequency unit in general. In the resource mapping example, UCI and UL-SCH coded bits are modulated into coded symbols and multiplexed and transmitted on PUSCH. An example of such an encoding scheme can be found in FIG. 16. There may be a separately coded UCI code chain CB3 (1624 in FIG. 16) that is dedicated to protect the most important UCI content, for example, which is HARQ-ACK in this example, and in FIG. 20 a resource mapping for this type of CB is shown as “HARQ-ACK with parity bits (coupled bits) on HARQ-ACK resource”. HARQ-ACK bits (information bits and/or parity bits) may be embedded into UL-SCH data for joint encoding, shown as CB4 or 1636 in FIG. 16, and a resource mapping for this type of CB is referred to as “Joint UCI (HARQ-ACK) and UL-SCH coded symbol” in FIG. 20. There are other UCI code chains, such as the code chains for CB1 (1618) and CB2 (1306) in FIG. 16, which jointly encode different UCI contents that have the same or different priorities. A resource mapping for this type of CB is shown as “Joint UCI coded symbol on UCI resource” in FIG. 20.

For the resource multiplexing, in the first step, there may be resource allocations reserved for certain UCI content, for example HARQ-ACK resources in the reserved locations shown in FIG. 20. In one example of this disclosure, the coded symbols that are modulated using the UCI coupling bits as systematic bits of the output of the joint UCI and UL-SCH coding (CB4 in FIG. 16 for example) may be mapped to corresponding locations that are the same as the locations for the UCI code. For example, in the coding example described by FIG. 16, the symbols generated from HARQ-ACK coded bits in CB3 as well as coupling bits of HARQ-ACK in CB4 may both be mapped to the HARQ-ACK reserved resources. HARQ-ACK bits from CB3 may be mapped first and HARQ-ACK coupling bits may be mapped afterwards, but other ordering are also possible. If the coding is as described in FIG. 15, and all HARQ-ACK coded bits are coupling bits and embedded into the UL-SCH code chain, then those HARQ-ACK coupling bits may be mapped into HARQ-ACK reserved locations. In FIG. 20, the HARQ ACK reserved locations are shown as “HARQ-ACK with parity bits (coupling bits) on HARQ-ACK resource”. In some other examples, the HARQ-ACK coupling bits may still be considered as part of the UL-SCH code chain and mapped the same way as other UL-SCH coded symbols.

After HARQ-ACK symbols are mapped, in the second step, the other coded symbols from UCI code chain are then mapped to the resources. The mapping may be following a frequency first and then time second manner as in the example of FIG. 20, but other mapping order may be also possible. In the coding example in FIG. 16, both CB1 and CB2 belong to the other UCI code chains, and they are mapped to the time frequency resources based on the order of the importance of the UCI contents. This ordering may be predefined based on importance of different UCI content. For example, CB1 may be mapped first, followed by CB2. In FIG. 20, the mapping of CB1 and CB2 on the time frequency resources are shown as “Joint UCI coded symbol on UCI resource” as both CBs contain joint encoding of multiple UCI types, with or without different priorities. In some other examples, only 1 UCI may be coded on the coding chain, and the resultant CBs can be mapped in the same manner as the joint UCI code chain. Note that when mapping to the time frequency resources, some locations may be reserved for other uses, and should be avoided. For example, in FIG. 20, DMRS are reserved at certain locations and should be avoided when mapping the UCI resources (as well as UL-SCH resources).

After symbols from all UCI code chains are mapped, in the third step, the UL-SCH symbols from the joint UCI and UL-SCH code chain are mapped to the resources. The mapping to the resources should follow the resources already mapped by the UCI symbols and avoid the HARQ-ACK reserved locations as well as other reserved locations, such as DMRS. In some scenarios, the number of coded symbols produced from the UL-SCH rate matching step described earlier may be more than the remaining available REs in the overall PUSCH resources, in this case, the coded symbols may either do “rate matching” or “puncturing” around the UCI and HARQ-ACK reserved resources. For example, if a rate matching solution is used for avoiding the UCI resources, then the UL-SCH coded symbols may be mapped to the remaining resources in order by avoiding the UCI resources. In another example, if a “puncturing” solution is used for avoiding HARQ-ACK reserved resources, then the UL-SCH coded symbols may be mapped to the remaining resources, including HARQ-ACK reserved resources first, then the symbols that are mapped to the existing HARQ-ACK reserved locations will not be transmitted (that is, those symbols are punctured). As described earlier, in one example, all the joint UCI and UL-SCH coded symbols may be considered UL-SCH symbols and mapped accordingly. In some other examples, the UCI coupling bits of the systematic bits of the joint UCI and UL-SCH code chain may be mapped the same way as the corresponding UCI symbols, and in this scenario, the rest of the symbols of the joint UCI and UL-SCH coded symbols not including the coupling bits may be mapped the same way as the UL-SCH symbols as described above. In FIG. 20, this is shown as “Joint UCI (HARQ-ACK) and UL-SCH coded symbols (not including coupled bits)”.

### Overview

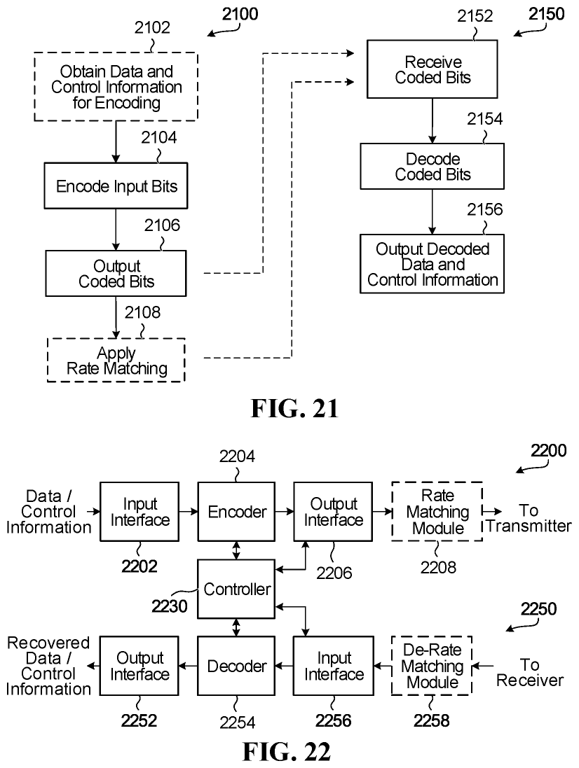

Various aspects of the present disclosure are described herein and shown in the drawings by way of example. FIG. 21 is a flow diagram illustrating more general example methods according to embodiments.

At the left, 2100 in FIG. 21 illustrates operations or features that may be provided or supported at an encoder or transmitter-side device, and at the right, 2150 illustrates operations or features that may be provided or supported at a decoder or receiver-side device. For ease of reference, a device at which encoding and/or transmitting features may be implemented or supported may be called a first communication device, and a device at which decoding and/or receiving features may be implemented or supported may be called a second communication device. Embodiments may involve either or both of such devices.

With reference first to 2100, the encoding at 2104 is intended to represent encoding input bits to generate coded bits.

The input bits include both data bits (which may include uplink data such as UL-SCH data for example) and bits associated with control information. The control information may be UCI for example. The bits associated with control information may include control information bits, coded bits generated from the control information (also referred to herein as second coded bits), or both. With reference to FIG. 13 as an example, the coupling bits at 1332 may include either or both of HP-ACK bits from 1322 and/or coded bits from CB1 at 1324. Other coupling bits examples are shown in FIGS. 14 to 18, and all of these coupling bits examples are examples of bits that are associated with control information and are part of the input bits encoded at 2104.

The encoding at 2104 involves jointly encoding the data bits and the bits associated with the control information. Consistent with embodiments disclosed herein, this may involve jointly encoding the data bits and the bits associated with the control information according to a first code (such as an LDPC code as shown in or described with reference to FIGS. 13 to 18) that is different from a second code (such as a polar code as shown in or described with reference to FIGS. 13 to 18) according to which second coded bits are generated from the control information. The first code being an LDPC code and the second code being a polar code is an example only, and other embodiments may involve one or both of these types of codes, or one or more different codes.

Even though there may be different codes for the joint encoding of the data bits and the bits associated with control information (the first code referenced above) and separate encoding of the control information (the second code referenced above), the joint encoding in distinct from techniques in which data and control are only separately encoded.

FIG. 21 illustrates outputting coded bits at 2106. These coded bits are generated by the encoding at 2104, and may be transmitted as illustrated by the dashed line from 2106 to 2152.

In some embodiments, the bits associated with the control information are, or include, the second coded bits generated from the control information. Thus, it should be appreciated that although second coded bits may be generated by separately encoding the control information, those second coded bits may or may not be included in coupling bits for joint encoding with data bits.

Joint encoding and separate encoding of control information may be provided, for example, in multiple encoding chains. Some embodiments may therefore also involve encoding the control information according to the second code to generate the second coded bits. This is not separately shown in FIG. 21, and may be part of encoding at 2104 for example. Inputs bits for this encoding to generate the second coded bits are the control information.

The outputting at 2106 may also involve outputting the second coded bits. In some embodiments, both the coded bits from the joint encoding and the second coded bits from separately encoding the control information are output. Some embodiments may involve transmitting bits, and accordingly a method may involve transmitting the coded bits in a data channel such as PUSCH. Coded bits generated by encoding the control information (also referred to herein as second coded bits), may also be transmitted, and in some embodiments a method involves transmitting the coded bits and the second coded bits in the same data channel.

The examples above refer to coded bits from the joint encoding and second coded bits generated from the control information. There may be other separate encoding as well. For example, FIGS. 13, 14, and 16 illustrate embodiments in which there are additional encoding chains for control information. This is illustrative of embodiments that involve encoding further control information to generate further coded bits (in CB2 and/or CB3 in FIGS. 13 and 14, or CB1 and/or CB2 in FIG. 16, for example). Such further coded bits may also be output. This separate encoding and output of further coded bits are not shown separately in FIG. 21 in order to avoid congestion in the drawing, but may be part of the encoding at 2104 and the outputting at 2106.

The first code and the second code referenced above are different codes. Other encoding chains (or encoding) may encode according to a further code that is the same as or different from the first code or the second code. As an example, in some embodiments encoding further control information involves encoding the further control information according to a further code of a same code type as the second code, or the second code may be used to generate further coded bits from such further control information. In the examples shown in FIGS. 13, 14, and 16, each of the control information encoding chains encodes control information according to the same type of code, which is a polar code in these examples.

The further control information may be of a same type as the control information for joint encoding, or of a different type. As an example, the further control information may be of the same type as the control information for joint encoding, but have a different priority than the control information. FIGS. 13, 14, and 16 illustrate examples in which the control information for joint encoding is HP-ACK and further (separately encoded) control information includes LP-ACK. HP-ACK and LP-ACK represent one example of control information of the same type but having different priorities.

The example in FIG. 16 is also illustrative of an embodiment in which separately encoded further control information (shown at 1612, 1614, 1616 in the second row) includes the control information for joint encoding (HP-ACK at 1622 is also shown in the second row at 1612) and additional control information (CSI-1 at 1614 and HP-SR at 1616). Encoding the further control information in such embodiments involves jointly encoding the control information (at 1612 for example) and the additional control information (at 1614, 1616 for example).

Coupling bits may include control information bits and/or second coded bits generated from the control information. All or some of the control information bits may be coupling bits, and the coupling bits may also or instead include all or some coded bits that are generated from the control information. In the context of second coded bits that are included in coupling bits in some embodiments, the second coded bits may include a subset of coded bits selected from among a set of coded bits generated by encoding the control information. In other words, not all of the coded bits generated by encoding the control information are necessarily included with data bits for the joint encoding. Thus, the set of coded bits may include the second coded bits (as coupling bits in the input bits for joint encoding) and additional coded bits. As an example discussed at least above, when coded bits from separate encoding of control information are used for coupling, the coded bits can be selected from part of the original coded bits (for the UCI code chain in FIG. 15 for example, where the full set of coded bits from separately encoding the UCI are shown as CB1 at 1506). Selecting coded bits as coupling bits for joint encoding with data bits may support chase combining (CC) in decoding. Selecting different coded bits, from the mother code output 1505 in FIG. 15 for example, may support a partial IR scheme.

Some embodiments may involve rate matching, and accordingly a method may involve applying rate matching as shown at 2108. The rate matching may involve outputting some or all coded bits for transmission, and may be applied to coded bits from any encoding chain. The example shown in FIG. 17 illustrates, at 1712, coded bits from the UCI encoding chain that are not transmitted after rate matching. Coded bits may be selected as coupling bits from among the full set of coded bits, including the non-transmitted bits in the example shown. Selection of coupling bits from among non-transmitted bits is also an example of selecting one or more bits from a full set of coded based on rate matching.

More generally, one or more bits may be selected (or in other words a method may involve selecting one or more bits) based on rate matching. Rate matching may involve, for example, puncturing, shortening (possibly in combination with puncturing), or repetition. One or more bits may be selected, for joint coding with data bits, from punctured bits (at the beginning) of the set of coded bits where the rate matching involves puncturing, from shortened bits (at the end) of the set of coded bits where the rate matching involves shortening, or from bits other than repeated bits of the set of coded bits where the rate matching involves repetition. In the example shown in FIG. 17, coupling bits may be selected from the bits shown at 1712, which may include punctured bits and/or shortened bits.

Transmission of rate-matched coded bits, which may include transmitting rate-matched coded bits from any one or more of multiple encoding chains in some embodiments (such as any of the coded bits, the set of coded bits generated by encoding the control information, or the further coded bits referenced above) is illustrated by the dashed line from 2108 to 2152.

Some embodiments may involve determining a TBS based on allocated resources, and determining a payload size for the data bits based on the transport block size. Determining the transport block size may take into account resources allocated for the control information, or determining the payload size may be further based on the bits associated with the control information.

An example of determining a TBS is provided elsewhere herein, in the context of determining the transport block size (number of the information bits for the transport block) of PUSCH in current NR standard ([3GPP TS 38.214 version 17.5.0 Section 6.1.4]). Determining a TBS may involve first determining the number of REs allocated for PUSCH within a slot, consistent with the example above, by determining the number of REs allocated for PUSCH within a PRB, and determining the total number of REs allocated for PUSCH. Some embodiments may involve determining an unquantized intermediate variable based on the number of REs allocated for PUSCH, and determining the TBS based on that unquantized intermediate variable, possibly by reading the TBS from a table that maps unquantized intermediate variable values to TBS values.

As described at least above, TBS determinations may be determined by taking into account the UCI resources, which can result in less impact on the code rate of UL-SCH (to make it closer to the target code rate). This is one example of how determining TBS may take into account resources allocated for the control information. In another example herein, TBS is unchanged and based on REs allocated for all PUSCH without removing REs allocated for UCI.

In some embodiments, determining the payload size may be further based on the bits associated with the control information. For example, as described at least above, after determining TBS the UL-SCH payload size may be obtained by removing the size of UCI coupling bits (also referred to herein as the bits associated with the control information) from TBS. In another example, the UL-SCH payload size may be obtained directly from TBS without removing the size of UCI coupling bits.

A method may involve determining UCI payload and UCI rate matching, or more generally control information payload size and control information rate matching. This step may include determining the control information payload size and then control information rate matching, consistent with the example shown at 1904 and 1906 in FIG. 19. Control information payload size may be given or determined based on the control information content that is to be transmitted. As described by way of example above, if the control information is a HARQ-ACK, and the HARQ-ACK includes 2 bits that are used to transmit 2 HARQ feedback for 2 TBs with 1 bit each, then the control information payload is 2 bits. In another example, if the control information is a CSI report, then the number of bits for the CSI may also be determined based on how many bits are to be reported from this particular CSI format. The control information rate matching process may be determined based on the given control information payload size.

In an example above, for control information (UCI as an example) rate matching, the number of coded symbols calculated or otherwise determined from UCI resources may include both the UCI coded bits and the coupling bits. Consistent with a HARQ-ACK example above, the number of coded symbols for a HARQ-ACK and part 1 of CSI transmitted in a PUSCH may be determined based on different beta offset and two equations provided by way of example above, similar to a UCI rate matching scheme in [3GPP TS 38.212 V17.5.0 Section 6.3.2.4.1].

Resource priority may be given to high priority control information such as UCI, but in some examples the number of coded symbols determined using control information resources can represent the sum of, for example, UCI coded bits and coupling bits (also referred to herein as bits associated with control information) for the joint coding instead of UCI coded bits alone. Where the number of coded symbols determined for control information does not include additional coupling bits, that number can be directly used for generating the number of coded symbols for resource multiplexing and transmission of the control information, and that number of coded symbols will be generated and used for resource mapping and transmission for control information. Where the number of coded symbols determined for control information includes additional coupling bits, then the number of coupling bits may be removed. That is, the number of actual coded symbols generated for the control information separate code chain for resource mapping and transmission is given by a smaller number of coupling symbols, where smaller number of coupling symbols may be the number of coupling bits divided by the modulation order. The additional number of coupling bits may be generated from the separate code chain for use in embedding with data in another code chain for joint encoding.

A next step in some embodiments is determining data rate matching, to determine the coded bits to be selected in a joint encoding output. After TBS determination for example, a method may involve determining a payload size of data and embedded coupling bits that are put together for joint encoding. The number of coded bits for output may be determined based on the available REs to transmit the jointly encoded data and control information, in PUSCH resources for example, as determined in the TBS determination process. In some examples, the data rate matching process for jointly encoded data and control information is determined without considering that control information may be multiplexed on the same resource. In this situation, rate matching may be determined such that the number of coded bits that are actually transmitted or otherwise output may be reduced due to the control information, through the process of data and control multiplexing when mapping to time and frequency resources. The number of coded bits selected for the rate matching process may or may not consider the resources occupied by the control information. In some other examples, the rate matching process for jointly encoded data and control information may consider that the control information occupies resources when selecting coded bits from the joint encoding output. For example, the number of coded bits selected from the joint encoding output may be determined based on available REs calculated after removing the control information resources, similar to the example of TBS determination considering control information resources.

A next step may involve data and control multiplexing, which determines how to map coded symbols for jointly coded data and control information, and coded symbols for the control information into time and frequency resources, which are resources allocated for PUSCH in some embodiments.

Mapping coded symbols to time frequency resources (REs) may follow a predefined order and rule, which may be referred to as mapping coded symbols to respective resources according to a mapping order. mapping coded symbols for the second coded bits to respective resources, according to a mapping order, such as mapping coded symbols for control information (which are coded symbols for second coded bits according to terminology in some examples herein) to resources first, and then mapping the coded symbols for combined data and control information (which are coded symbols for coded bits according to terminology in some examples herein) to other resources. This type of mapping order is consistent with mapping UCI first, then UL data, for example.

Thus, a method that involves transmitting may involve mapping coded symbols for the second coded bits (separately encoded control information) to resources for transmission of the control information and, after mapping the coded symbols for the second coded bits, mapping coded symbols for the coded bits (from joint encoding) to resources for transmission of data. This is different from control first, data second mapping in that the jointly encoded data/control information part is considered and treated as UL data in some embodiments, and coded symbols are mapped to resources according to a UL data mapping rule, such as to map last, and apply rate matching and/or otherwise avoid existing control information resources such as UCI resources. Another difference is that coupling bits (also referred to herein as bits associated with control information) may be mapped differently from the rest of the jointly encoded bits. Considering systematic codes as an example, the coupling bits (bits associated with the control information) may be mapped to control information resources such as UCI resources, while the rest of the jointly encoded bits (data and parity) are mapped to data resources such as UL data resources. This mapping to data resources may be after the mapping to control resources, and may avoid control resources.

This latter example of resource mapping may be described as an example in which the second coded bits (generated from the control information) and the coded bits (from jointly encoding data and the bits associated with the control information) both include the bits associated with the control information. Coded symbols for the second coded bits are mapped to resources for transmitting the control information, and mapping the coded symbols for the coded bits involve mapping coded symbols for only coded bits other than the bits associated with the control information, which are already mapped to control resources.

The resources referenced above may be or include PUSCH resources.

Embodiments consistent with the present disclosure may provide or support other features, and/or different features than those shown in FIG. 21. For example, in some embodiments coded bits generated by the encoding at 2104 may be output by an encoder at 2106 for further processing or handling, and may or may not be transmitted as shown by the dashed line from 2106 to 2152. The coded bits may be output to memory, for example.

Obtaining data and control information for encoding, as shown at 2102 in FIG. 21, may be performed or supported separately from the encoding at 2104 and/or the outputting at 2106. The obtaining at 2102 may involve any of various operations, such as any one or more of the following: collecting or otherwise receiving data outputs and/or control information from one or more devices and/or services; accessing data and/or control information in a memory; encoding or otherwise pre-processing data and/or control information (by selecting coupling bits for the joint data/control encoding for example) before the encoding at 2104.

Another example of features that may be provided in some embodiments but are not explicitly shown in FIG. 21 relates to signaling. Some embodiments may involve transmitting and/or receiving signaling or any of various types of indications related to encoding and/or transmission for example. More generally, embodiments may involve communicating, in a wireless communication network, signaling indicative of any of various parameters. Parameters related to one or more of coupling bit selection, encoding, rate matching, transmission, reception, or decoding may be indicated in signaling.

Such communicating of signaling may involve transmitting the signaling by an encoder/encoding device or a transmitter/transmitting device that is to transmit coded bits, to a decoder/decoding device or a receiver/receiving device. The communicating may also or instead involve receiving the signaling by a decoder/decoding device or a receiver/receiving device from an encoder/encoding device or a transmitter/transmitting device. Signaling need not necessarily be between, or only between, communication devices by which coded bits are to be transmitted or received. For example, a network device such as a gNB or a base station may transmit signaling to configure parameters at one or more communication devices. Therefore, a method may involve a network device transmitting signaling, and an encoder/encoding device or a transmitter/transmitting device receiving signaling from the network device, and/or a decoder/decoding device or a receiver/receiving device receiving signaling from the network device.

At 2150, FIG. 21 illustrates various decoding and/or receiving counterparts of features shown at 2100. From a receiving device perspective, the receiving at 2152 is intended to represent receiving coded bits generated by encoding input bits that include data bits and bits associated with control information. The input bits would have been jointly encoded according to a first code that is different from a second code according to which second coded bits were generated from the control information, as described by way of example at least above.

Decoding of the received coded bits is shown at 2154, and at 2156 FIG. 21 illustrates outputting decoded data bits and bits associated with the control information. Decoded bits may also be referred to as recovered data bits and bits associated with the control information, decoded from the received coded bits.

The bits associated with the control information may include control information bits and/or the second coded bits generated from the control information.

In some embodiments, the coded bits from joint encoding and the second coded bits generated from the control information are transmitted, and accordingly a method (or the receiving at 2152) may involve receiving the second coded bits. A method (or the decoding at 2154) may involve decoding the second coded bits. Similarly, a method (or the outputting at 2156) may involve outputting recovered control information decoded from the received second coded bits.

Some embodiments may involve joint decoding of coded bits. For example, a method (or the decoding at 2154) may involve decoding the received coded bits (generated by jointly encoding the input bits including data bits and bits based on control information) based on the recovered control information decoded from the received second coded bits. With reference to FIG. 18, for example, successful decoding of CB1 (which includes the second coded bits from separately encoding the control information, UCI in this example) can aid in decoding CB4 (which includes the coded bits from jointly encoding data bits and bits associated with the control information). Similarly, successful decoding of CB4 may aid in decoding CB1.

Decoding received coded bits based on recovered control information decoded from received second coded bits is consistent with a decoding example above, and may involve a Step 1 to combine channel LLR of UCI coded bits and attempt to decode a polar code, and a Step 2 to, if the UCI coupling bits have been decoded from the polar decoder, assign large LLR as the corresponding coupling bits in the LDPC code used for joint UCI and UL-SCH coding, and attempt to decode the LDPC code. In one example of decoding received second coded bits based on recovered bits from decoding received coded bits (from joint encoding), decoding may involve Step 2, and a Step 3 to combine the extrinsic LLR of UCI coupling bits from LDPC decoding with channel LLR determined based on the received second coded bits (a signal of the coupling bits) as the reliability input for the polar code and attempt to decode polar code.

Embodiments related to receiving and/or decoding may include other features, such as any one or more of the following features, for example, which are also discussed elsewhere herein:
the bits associated with the control information may be or include the second coded bits generated from the control information;
the first code may be an LDPC code;
the second code may be a polar code;
the further control information referenced above may be of a same (or different) type as the control information;
the further control information may be of the same type as the control information and have a different priority than the control information;
the further control information may include the control information and additional control information;
the further coded bits may have been generated by jointly encoding the control information and the additional control information;
the second coded bits may include a subset of coded bits among a set of coded bits generated by encoding the control information;
the set of coded bits may include the second coded bits and additional coded bits;
the second coded bits may include one or more bits selected, based on rate matching applied to the set of coded bits, from the set;
the one or more bits may have been selected from punctured bits of the set of coded bits where the rate matching involves puncturing;
the one or more bits may have been selected from shortened bits of the set of coded bits where the rate matching involves shortening;
the one or more bits may have been selected from bits other than repeated bits of the set of coded bits where the rate matching involves repetition;
the data bits may be or include uplink data;
the control information may be or include UCI.

A method related to receiving coded bits and/or decoding coded bits may also provide or support other features, such as receiving or decoding feature counterparts of features described herein in the context of methods related to encoding and/or transmitting coded bits.

For example, further coded bits may be generated by encoding further control information, and accordingly a method (or the receiving at 2152) may involve receiving further coded bits generated by encoding further control information. A method (or the decoding at 2154) may involve decoding the further coded bits. Similarly, a method (or the outputting at 2156) may involve outputting recovered further control information decoded from the received further coded bits. The further coded bits may have been generated by encoding the further control information according to a further code, which may be of a same or different code type as the second code. In an embodiment, the second code is used to encode the further control information to generate the further coded bits.

As another example, coded bits may be transmitted in a data channel, and accordingly a method (or the receiving at 2152) may involve receiving the coded bits (from jointly encoding the data bits and the bits associated with the control information) in a data channel, and may also involve receiving the second (and/or further) coded bits in the data channel. An example of a data channel in which coded bits may be transmitted is PUSCH.

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

An apparatus may include a processor that is configured, by executing programming for example, to cause the apparatus to perform a method or operations, or to provide or support features, disclosed herein. An apparatus may also include a non-transitory computer readable storage medium, coupled to the processor, storing programming for execution by the processor. In FIG. 3, for example, the processors 210, 260, 276 may each be or include one or more processors, and each memory 208, 258, 278 is an example of a non-transitory computer readable storage medium, in an ED 110 and a TRP 170, 172. A non-transitory computer readable storage medium need not necessarily be provided only in combination with a processor, and may be provided separately in a computer program product, for example.

As an illustrative example, programming stored in or on a non-transitory computer readable storage medium may include instructions to or to cause a processor to, or a processor, device, or other component may otherwise be configured to, encode input bits to generate coded bits as disclosed herein, and to output the coded bits.

Apparatus embodiments are not limited to the foregoing examples, or to processor-based or programming-based embodiments. An apparatus may also or instead include, for example, an encoder for encoding input bits to generate coded bits, and an interface, coupled to the encoder, for outputting the coded bits.

The apparatus may be a communication device or a component implemented in a communication device. For example, the apparatus implemented in a communication device may be an integrated circuit, which in some contexts may be known by other names, such as chip, modem, modem chip, baseband chip, or baseband processor. In some implementations, one or more integrated circuits can be packaged into a system-on-chip, a system-in-package, or a multi-chip module. The apparatus may comprise one or more integrated circuits or comprise one or more integrated circuits and other discrete components.

FIG. 22 is a block diagram illustrating an apparatus according to an embodiment. At 2200, FIG. 22 illustrates components of an example apparatus in which or in conjunction with which transmitting and/or encoding features may be implemented, and components of an example apparatus in which or in conjunction with which receiving and/or decoding features may be implemented are illustrated at 2250. A controller 2230 may be provided in either of these types of apparatus. In some embodiments, an apparatus may include both transmitting and receiving features, and either or both of encoding features or decoding features. In the example shown in FIG. 22, an apparatus with all of the illustrated components supports both encoding features and decoding features, as well and transmitting features and receiving features.

For encoding features and transmitting features, the example apparatus in FIG. 22 includes an input interface 2202, an encoder 2204 coupled to the input interface, an output interface 2206, optionally a rate matching module 2208, and a controller 2230 coupled to the encoder and the output interface. The controller may also or instead be coupled to one or more other components, but connections are not shown in FIG. 22 to avoid congestion in the drawing. Data and control information for encoding by the encoder 2204 is shown as an input to the input interface 2202, and coded bits are output through the output interface 2206. Although shown as a separate component in FIG. 22, the output interface 2206 for transmitting or otherwise outputting codewords may be provided by, incorporated into, or coupled to the encoder 2204. Similarly, although shown as a separate input interface 2202 in FIG. 22, an interface through which data and control information, or input bits for encoding, are obtained by the encoder 2204 may be provided by, incorporated into, or coupled to the encoder.

The rate matching module 2208 may be provided in some embodiments, where rate matching is to be applied to coded bits prior to transmission. A transmitter for transmitting coded bits, which may be rate-matched coded bits in some embodiments, is not separately shown in FIG. 22 to avoid congestion in the drawing.

Encode-side or transmit-side features or functions, and other features or functions herein, may be implemented in any of various ways, such as in hardware, firmware, or one or more components that execute software. The present disclosure is not limited to any specific type of implementation, and implementation details may vary between different devices.

Data and control information or input bits for encoding may be obtained, and coded bits may be transmitted or otherwise output, via any of various types of interface, including a communication interface in the case of transmitting coded bits or receiving input bits for encoding. Embodiments are not in any way restricted to any particular type of interface, the implementation of which may be based at least in part on how data and control information or input bits are to be obtained and how coded bits are to be output.

In an embodiment, an apparatus includes an encoder such as the encoder 2204 for encoding input bits to generate coded bits as disclosed herein. An interface may be provided and coupled to an encoder, and in the example shown the output interface 2206 is coupled to the encoder 2204 for outputting the coded bits.

More generally, an apparatus or a component thereof such as an encoder 2204 or a processor may be configured to encode (or for encoding) input bits to generate coded bits as disclosed herein. An apparatus or a component thereof such as an interface 2206, which may be coupled to the encoder 2204, may be configured to output (or for outputting), or programming may include instructions to output (or for outputting) or to cause a processor to output, the coded bits as disclosed herein.

Embodiments related to such apparatus or non-transitory computer readable storage media may include any one or more of the following features, for example, which are also discussed elsewhere herein:
the bits associated with the control information may be or include second coded bits generated from the control information;
the first code may be an LDPC code;
the second code may be a polar code;
the apparatus or a component thereof such as the encoder 2204 may be configured to encode (or for encoding), or programming may include instructions to encode (or for encoding), or to cause a processor to encode the control information according to the second code to generate the second coded bits,
the apparatus or a component thereof such as the interface 2206 may be configured to output (or for outputting), or programming may include instructions to output (or for outputting), or to cause a processor to output the second coded bits;
the apparatus or a component thereof such as the encoder 2204 may be configured to encode (or for encoding), or programming may include instructions to encode (or for encoding), or to cause a processor to encode further control information to generate further coded bits;
the apparatus or a component thereof such as the interface 2206 may be configured to output (or for outputting), or programming may include instructions to output (or for outputting), or to cause a processor to output the further coded bits;
the apparatus or a component thereof such as the encoder 2204 may be configured to encode (or for encoding), or programming may include instructions to encode (or for encoding), or to cause a processor to encode the further control information according to a further code of a same code type as the second code;
the further control information may be of a same type as the control information;
the further control information may have a different priority than the control information;
the further control information may include the control information and additional control information;
the apparatus or a component thereof such as the encoder 2204 may be configured to jointly encode (or for jointly encoding), or programming may include instructions to jointly encode (or for jointly encoding), or to cause a processor to jointly encode the control information and the additional control information;
the second coded bits may include a subset of coded bits selected from among a set of coded bits generated by encoding the control information;
the set of coded bits may include the second coded bits and additional coded bits;
the apparatus or a component thereof such as the encoder 2204, the interface 2206, or a rate matching module 2208 coupled to the interface 2206, may be configured to apply (or for applying), or programming may include instructions to apply (or for applying), or to cause a processor to apply rate matching to the set of coded bits;
the second coded bits may include one or more bits selected, based on the rate matching, from the set;
the one or more bits may be selected from punctured bits of the second coded bits where the rate matching involves puncturing;
the one or more bits may be selected from shortened bits of the set of coded bits where the rate matching involves shortening;
the one or more bits may be selected from bits other than repeated bits of the set of coded bits where the rate matching involves repetition;
the apparatus or a component thereof such as the encoder 2204, the interface 2206, or a transmitter coupled to the interface 2206, may be configured to transmit (or for transmitting), or programming may include instructions to transmit (or for transmitting), or to cause a processor to transmit the coded bits and transmit the second coded bits in a data channel;
the apparatus or a component thereof such as the encoder 2204, the interface 2206, or a transmitter coupled to the interface 2206, may be configured to determine (or for determining), or programming may include instructions to determine (or for determining), or to cause a processor to determine a transport block size based on allocated resources, and determine a payload size for the data bits based on the transport block size;
determining the transport block size may take into account resources allocated for the control information;
determining the payload size may be further based on the bits associated with the control information;
the apparatus or a component thereof such as the encoder 2204, the interface 2206, or a transmitter coupled to the interface 2206, may be configured to map (or for mapping), or programming may include instructions to map (or for mapping), or to cause a processor to map coded symbols for the second coded bits to resources for transmission of the control information and, after mapping the coded symbols for the second coded bits, map coded symbols for the coded bits to resources for transmission of data;
the second coded bits and the coded bits may both include the bits associated with the control information, in which case the apparatus or a component thereof such as the encoder 2204, the interface 2206, or a transmitter coupled to the interface 2206, may be configured to map (or for mapping), or programming may include instructions to map (or for mapping), or to cause a processor to map the coded symbols for the coded bits by mapping coded symbols for only coded bits other than the bits associated with the control information;
the resources may be or include PUSCH resources;
the data bits may be or include uplink data;
the control information may be or include UCI.

With reference again to FIG. 22, the example apparatus also includes components to provide or support receiving and decoding features. These components may be provided separately in a decoding or receiving device, or together with other components to provide or support decoding or receiving features together with encoding or transmitting features.

An input interface 2256 is coupled to a decoder 2254, and these components are also coupled to the controller 2230, which as described at least above may also or instead be coupled to one or more other components. The decoder 2254 is coupled to an output interface 2252. FIG. 22 also illustrates recovered data and control information as output from the output interface 2252, and coded bits are inputs received by the interface 2256. The interface 2256 may be provided by, incorporated into, or coupled to the decoder 2254, and similarly an interface 2252 through which recovered data and control information are output by the decoder may be provided by, incorporated into, or coupled to the decoder. In embodiments that involve rate matching, a de-rate matching module 2258 may be provided to implement counterpart receive-side features of transmit-side rate matching.

Decode-side or receive-side features or functions, and other features or functions herein, may be implemented in any of various ways, such as in hardware, firmware, or one or more components that execute software. The present disclosure is not limited to any specific type of implementation, and implementation details may vary between different devices, for example.

Coded bits may be received or otherwise obtained, and a recovered bit sequence may be output, via any of various types of interface, including a communication interface in the case of receiving coded bits or transmitting recovered data and control information. Embodiments are not in any way restricted to any particular type of receiver or interface, the implementation of which may be based at least in part on how code bits for decoding are to be obtained and how recovered data and control information are to be output. Encoder and decoder interfaces are shown separately in FIG. 22 to illustrate that encoding and decoding features may be implemented independently. However, it should be appreciated that a single device or equipment may support both encoding and decoding, in which case an encoder and a decoder may be coupled to the same interface(s) at 2202, 2252. For example, the encoder 2204 and the decoder 2254 may be coupled to the same interface(s) to obtain data and control information or input bits for encoding by the encoder and to output recovered data and control information decoded from received coded bits by the decoder. The encoder 2204 and the decoder 2254 may also or instead be coupled to the same interface(s) to output coded bits that are generated by the encoder and receive coded bits for decoding by the decoder.

In an embodiment, an apparatus includes a decoder such as the decoder 2254 for decoding, from received coded bits, recovered data and bits associated with control information. The interface 2256 is coupled to the decoder, for receiving the coded bits as disclosed herein. An apparatus may also include an interface such as the output interface 2252 in some embodiments, for outputting recovered data bits and bits associated with control information. More generally, an apparatus or a component thereof such as a decoder 2254 or a processor may be configured to decode (or for decoding) coded bits, or programming may include instructions to decode (or for decoding) coded bits. An apparatus or a component thereof such as an interface 2256 coupled to the decoder 2254, may be configured to receive (or for receiving) or to otherwise obtain (or for obtaining), or programming may include instructions to receive (or for receiving) or to otherwise obtain (or for obtaining) or to cause a processor to receive or otherwise obtain, the coded bits. Receiving may involve receiving the coded bits from a first communication device by a second communication device in a wireless communication network for example.

As in examples described in further detail at least above, the coded bits were generated by jointly encoding input bits, and the input bits include data bits and bits associated with control information. The input bits would have been jointly encoded according to a first code that is different from a second code according to which second coded bits were generated from the control information.

Embodiments related to such apparatus or non-transitory computer readable storage media may include any one or more of the following features, for example, which are also discussed elsewhere herein:
the bits associated with the control information may be or include the second coded bits generated from the control information;
the first code may be an LDPC code;
the second code may be a polar code;
the apparatus or a component thereof such as the decoder 2254, the interface 2256, or a receiver coupled to the interface 2256, may be configured to receive (or for receiving), or programming may include instructions to receive (or for receiving), or to cause a processor to receive the second coded bits;
the apparatus or a component thereof such as the decoder 2254 may be configured to decode (or for decoding), or programming may include instructions to decode (or for decoding), or to cause a processor to decode, from the received second coded bits, recovered control information;
the apparatus or a component thereof such as the decoder 2254 may be configured to decode (or for decoding), or programming may include instructions to decode (or for decoding), or to cause a processor to decode the received coded bits based on the recovered control information decoded from the received second coded bits;
the apparatus or a component thereof such as the decoder 2254, the interface 2256, or a receiver coupled to the interface 2256, may be configured to receive (or for receiving), or programming may include instructions to receive (or for receiving), or to cause a processor to receive further coded bits generated by encoding further control information;
the apparatus or a component thereof such as the decoder 2254 may be configured to decode (or for decoding), or programming may include instructions to decode (or for decoding), or to cause a processor to decode, from the received further coded bits, recovered further control information;
the further coded bits may have been generated by encoding the further control information according to the second code, or a further code of a same (or different) code type as the second code;
the further control information may be of a same (or different) type as the control information;
the further control information may have a different priority than the control information;
the further control information may include the control information and additional control information;
the further coded bits may have been generated by jointly encoding the control information and the additional control information;
the second coded bits may be or include a subset of coded bits among a set of coded bits generated by encoding the control information;
the set of coded bits may include the second coded bits and additional coded bits;
the second coded bits may include one or more bits selected, based on rate matching applied to the set of coded bits, from the set;
the one or more bits may have been selected from punctured bits of the set of coded bits where the rate matching involves puncturing;
the one or more bits may have been selected from shortened bits of the set of coded bits where the rate matching involves shortening;
the one or more bits may have been selected from bits other than repeated bits of the set of coded bits where the rate matching involves repetition;
the apparatus or a component thereof such as the decoder 2254, the interface 2256, or a receiver coupled to the interface 2256, may be configured to receive (or for receiving), or programming may include instructions to receive (or for receiving), or to cause a processor to receive the coded bits in a data channel;
the apparatus or a component thereof such as the decoder 2254, the interface 2256, or a receiver coupled to the interface 2256, may be configured to receive (or for receiving), or programming may include instructions to receive (or for receiving), or to cause a processor to receive the second coded bits in the data channel;
the data channel may be PUSCH;
the data bits may be or include uplink data;
the control information may be or include uplink control information (UCI).

Other features disclosed herein may also or instead be provided or supported in apparatus embodiments.

Apparatus embodiments are not in any way restricted to single devices. A system, for example, may include a first communication device and a second communication device. The first communication device may be configured to encode input bits to generate coded bits, and to transmit the coded bits. The second communication device may be configured to receive and decode the coded bits. The input bits may include data bits and bits associated with control information. The input bits are encoded by jointly encoding the data bits and the bits associated with the control information, and jointly encoding the data bits and the bits associated with the control information involves jointly encoding the data bits and the bits associated with the control information according to a first code. The first code is different from a second code according to which second coded bits are generated from the control information.

More generally, other features disclosed herein may also or instead be provided in method, apparatus, and/or system embodiments.

Some aspects of the present disclosure may achieve or enable benefits such as:
UCI reliability enhancement without additional UCI repetition
Minimum impact on PUSCH
UCI can still be decoded first to minimize delay
Polar code rate matching scheme that helps improve performance
Compatible or easy to describe standard definition of UCI UL-SCH multiplexing
Decoding complexity does not increase significantly because only hard decoding is done for polar code

The present disclosure encompasses various embodiments, including not only method embodiments, but also other embodiments such as apparatus embodiments and embodiments related to non-transitory computer readable storage media. Embodiments may incorporate, individually or in combinations, the features disclosed herein.

Although this disclosure refers to illustrative embodiments, this is not intended to be construed in a limiting sense. Various modifications and combinations of the illustrative embodiments, as well as other embodiments of the disclosure, will be apparent to persons skilled in the art upon reference to the description.

For example, embodiments are described herein primarily in the context of uplink data and control information. However, features disclosed herein may also or instead be applied to downlink, in which case data and control information may include downlink data and DCI for example. Other scenarios are also possible.

Features disclosed herein in the context of any particular embodiments may also or instead be implemented in other embodiments. Method embodiments, for example, may also or instead be implemented in apparatus, system, and/or computer program product embodiments. In addition, although embodiments are described primarily in the context of methods and apparatus, other implementations are also contemplated, as instructions stored on one or more non-transitory computer-readable media, for example. Such media could store programming or instructions to perform any of various methods consistent with the present disclosure.

The description and drawings are, accordingly, to be regarded simply as an illustration of some embodiments of the disclosure as defined by the appended claims, and are contemplated to cover any and all modifications, variations, combinations or equivalents that fall within the scope of the present application. Therefore, although embodiments and potential advantages have been described in detail, various changes, substitutions and alterations can be made herein without departing from the application as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present application, processes, machines, manufacture, compositions of matter, means, methods, or steps, presently existing or later to be developed, that perform substantially the same function or achieve substantially the same result as the corresponding embodiments described herein may be utilized according to the present application. Accordingly, the appended claims are intended to include within their scope such processes, machines, manufacture, compositions of matter, means, methods, or steps.

Moreover, any module, component, or device exemplified herein that executes instructions may include or otherwise have access to a non-transitory computer readable or processor readable storage medium or media for storage of information, such as computer readable or processor readable instructions, data structures, program modules, and/or other data. A non-exhaustive list of examples of non-transitory computer readable or processor readable storage media includes magnetic cassettes, magnetic tape, magnetic disk storage or other magnetic storage devices, optical disks such as compact disc read-only memory (CD-ROM), digital video discs or digital versatile disc (DVDs), Blu-ray Disc™, or other optical storage, volatile and non-volatile, removable and nonremovable media implemented in any method or technology, random-access memory (RAM), read-only memory (ROM), electrically erasable programmable read-only memory (EEPROM), flash memory or other memory technology. Any such non-transitory computer readable or processor readable storage media may be part of a device or accessible or connectable thereto. Any application or module herein described may be implemented using instructions that are readable and executable by a computer or processor may be stored or otherwise held by such non-transitory computer readable or processor readable storage media.

The following Acronyms, Abbreviations, and Initialisms may be used herein:

| Full Name | Acronym/Abbreviation/Initialism |
|---|---|
| Long Term Evolution | LTE |
| New Radio | NR |
| Acknowledgement | ACK |
| Non-Acknowledgement | NACK |
| Base-Station | BS |
| Code Block | CB |
| Code Rate | CR |
| Channel Quality Indicator | CQI |
| Forward Error Correction | FEC |
| Hybrid Automatic Repeat Request | HARQ |
| Incremental redundancy | IR |
| Two-Dimensional Hybrid Automatic | 2D HARQ |
| Repeat Request | |
| Low Density Parity Check | LDPC |
| Long-Term Evolution | LTE |
| New Radio | NR |
| Retransmission | ReTx |
| Transmission | Tx |
| Transport Block | TB |
| User Equipment | UE |
| Vertical Code Block | VCB |
| Code Block Group | CBG |
| HARQ process number | HPN |
| Downlink control information | DCI |
| Physical downlink shared channel | PDSCH |
| New Data Indicator | NDI |
| Physical uplink control channel | PUCCH |
| Scheduling request | SR |
| Logical Channel | LC |
| Multiple Access | MA |
| Quality of Service | QoS |
| ultra-reliable low latency | URLLC |
| communications | |
| Enhanced mobile broadband | eMBB |
| massive Machine Type | mMTC |
| Communications | |
| Modulation Coding Scheme | MCS |
| Physical uplink shared channel | PUSCH |
| Multiple input multiple output | MIMO |
| Downlink control information | DCI |
| Uplink control information | UCI |
| Group-common PDCCH | GC-PDCCH |
| Grant free | GF |
| Configured grant | CG |
| Uplink shared channel | UL-SCH |
| Medium Access Control | MAC |
| Medium Access Control- | MAC-CE |
| Control Element | |
| Code block group | CBG |
| Resource Block | RB |
| Resource Elements | RE |
| Transport block size | TBS |
| Cyclic redundancy check | CRC |
| Block error rate | BLER |
| Channel state information | CSI |
| Rank information | RI |
| Precoding matrix indicator | PMI |
| Chase combining | CC |
| CSI-RS resource indicator | CRI |
| Layer indicator | LI |

What is claimed is:

1. A method comprising:
encoding input bits to generate coded bits, the input bits comprising data bits and bits associated with control information, the encoding comprising jointly encoding the data bits and the bits associated with the control information, wherein jointly encoding the data bits and the bits associated with the control information comprises jointly encoding the data bits and the bits associated with the control information according to a first code that is different from a second code according to which second coded bits are generated from the control information; and
outputting the coded bits.

2. The method of claim 1, wherein the bits associated with the control information comprise the second coded bits generated from the control information.

3. The method of claim 1, wherein the first code is a low density parity check (LDPC) code, and the second code is a polar code.

4. The method of claim 1, wherein the second coded bits comprise a subset of coded bits selected from among a set of coded bits generated by encoding the control information, the set of coded bits comprising the second coded bits and additional coded bits.

5. The method of claim 1, further comprising:
determining a transport block size based on allocated resources; and
determining a payload size for the data bits based on the transport block size,
wherein determining the transport block size takes into account resources allocated for the control information, or determining the payload size is further based on the bits associated with the control information.

6. The method of claim 1, further comprising:
mapping coded symbols for the second coded bits to resources for transmission of the control information; and
after mapping the coded symbols for the second coded bits, mapping coded symbols for the coded bits to resources for transmission of data.

7. A method comprising:
receiving coded bits generated by jointly encoding input bits, the input bits comprising data bits and bits associated with control information, the input bits having been jointly encoded according to a first code that is different from a second code according to which second coded bits were generated from the control information; and
outputting recovered data bits and bits associated with the control information decoded from the received coded bits.

8. The method of claim 7, wherein the bits associated with the control information comprise the second coded bits generated from the control information.

9. The method of claim 7, wherein the first code is a low density parity check (LDPC) code, and the second code is a polar code.

10. The method of claim 7, wherein the second coded bits comprise a subset of coded bits among a set of coded bits generated by encoding the control information, the set of coded bits comprising the second coded bits and additional coded bits.

11. An apparatus comprising:
at least one processor; and
at least one memory coupled to the at least one processor and storing instructions that, when executed by the at least one processor, cause the apparatus to perform operations including:
encoding input bits to generate coded bits, the input bits comprising data bits and bits associated with control information, the encoding comprising jointly encoding the data bits and the bits associated with the control information, wherein jointly encoding the data bits and the bits associated with the control information comprises jointly encoding the data bits and the bits associated with the control information according to a first code that is different from a second code according to which second coded bits are generated from the control information; and
outputting the coded bits.

12. The apparatus of claim 11, wherein the bits associated with the control information comprise the second coded bits generated from the control information.

13. The apparatus of claim 11, wherein the first code is a low density parity check (LDPC) code, and the second code is a polar code.

14. The apparatus of claim 11, wherein the second coded bits comprise a subset of coded bits selected from among a set of coded bits generated by encoding the control information, the set of coded bits comprising the second coded bits and additional coded bits.

15. The apparatus of claim 11, wherein the operations further comprise:
determining a transport block size based on allocated resources; and
determining a payload size for the data bits based on the transport block size,
wherein determining the transport block size takes into account resources allocated for the control information, or determining the payload size is further based on the bits associated with the control information.

16. The apparatus of claim 11, wherein the operations further comprise:
mapping coded symbols for the second coded bits to resources for transmission of the control information; and
after mapping the coded symbols for the second coded bits, mapping coded symbols for the coded bits to resources for transmission of data.

17. An apparatus comprising:
at least one processor; and
at least one memory coupled to the at least one processor and storing instructions that, when executed by the at least one processor, cause the apparatus to perform operations including:
receiving coded bits generated by jointly encoding input bits, the input bits comprising data bits and bits associated with control information, the input bits having been jointly encoded according to a first code that is different from a second code according to which second coded bits were generated from the control information; and
outputting recovered data bits and bits associated with the control information decoded from the received coded bits.

18. The apparatus of claim 17, wherein the bits associated with the control information comprise the second coded bits generated from the control information.

19. The apparatus of claim 17, wherein the first code is a low density parity check (LDPC) code, and the second code is a polar code.

20. The apparatus of claim 17, wherein the second coded bits comprise a subset of coded bits among a set of coded bits generated by encoding the control information, the set of coded bits comprising the second coded bits and additional coded bits.
